(19) United States
(12) Patent Application Publication
(10) Pub. No.: US 2015/0115345 A1
(43) Pub. Date: Apr. 30, 2015

(54) VERTICAL MEMORY DEVICES AND METHODS OF MANUFACTURING THE SAME

(71) Applicants: Etienne Nowak, Suwon-si (KR); Dae-Sin Kim, Hwaseong-si (KR); Hye-Young Kwon, Suwon-si (KR); Jae-Ho Kim, Seoul (KR); Jin-Woo Park, Gunpo-si (KR); Ji-Woong Sue, Yongin-si (KR)

(72) Inventors: Etienne Nowak, Suwon-si (KR); Dae-Sin Kim, Hwaseong-si (KR); Hye-Young Kwon, Suwon-si (KR); Jae-Ho Kim, Seoul (KR); Jin-Woo Park, Gunpo-si (KR); Ji-Woong Sue, Yongin-si (KR)

(21) Appl. No.: 14/519,285

(22) Filed: Oct. 21, 2014

(30) Foreign Application Priority Data
Oct. 25, 2013 (KR) 10-2013-0127781

(51) Int. Cl. H01L 27/115; H01L 21/31

(52) U.S. Cl. CPC H01L 27/11582; H01L 27/11556; H01L 21/31
USPC 257/314; 438/268

(57) ABSTRACT

A vertical memory device includes a channel, a conductive pattern, gate electrodes, a bit line and a conductive line. A plurality of the channels and the conductive patterns extend in a vertical direction from a top surface of a substrate. The gate electrodes surround outer sidewalls of the channels and the conductive patterns. The gate electrodes are stacked in the vertical direction to be spaced apart from each other. The bit line is electrically connected to the channels. The conductive line is electrically connected to the conductive patterns.

### CROSS-REFERENCE TO RELATED APPLICATION

This application claims priority under 35 USC §119 to Korean Patent Application No. 10-2013-0127781, filed on Oct. 25, 2013 in the Korean Intellectual Property Office (KIPO), the contents of which are incorporated by reference herein in their entirety.

### BACKGROUND

1. Field

Example embodiments relate to vertical memory devices and methods of manufacturing the same. More particularly, example embodiments relate to non-volatile memory devices including vertical channels and methods of manufacturing the same.

2. Description of the Related Art

A conventional vertical memory device may include memory cells and insulation layers that are stacked alternately and vertically with respect to a surface of a substrate in order to realize a high degree of integration. In the vertical memory device, a channel may protrude vertically from the surface of the substrate. The memory cells and the insulation layers surrounding the channel may be repeatedly stacked.

### SUMMARY

Example embodiments provide a vertical memory device having a high degree of integration.

Example embodiments provide a method of manufacturing a vertical memory device having a high degree of integration.

According to example embodiments, there is provided a vertical memory device. The vertical memory device includes a plurality of channels, a plurality of conductive patterns, a plurality of gate electrodes, a bit line, and a conductive line. The plurality of the channels and conductive patterns extend in a vertical direction from a top surface of a substrate. The gate electrodes surround outer sidewalls of the channels and the conductive patterns. The gate electrodes are stacked in the vertical direction to be spaced apart from each other. The bit line is electrically connected to the channels. The conductive line is electrically connected to the conductive patterns.

In example embodiments, the conductive line is a common source line (CSL), and the conductive pattern is a CSL contact.

In example embodiments, the vertical memory device further comprises an impurity region at an upper portion of the substrate in contact with the conductive pattern.

In example embodiments, two or more of the plurality of the channels are disposed around one of the conductive patterns to form a cell string block.

In example embodiments, the vertical memory device may further include a dielectric layer structure between the channel and the gate electrodes, the dielectric layer structure extending from the top surface of the substrate in the vertical direction.

In example embodiments, the bit line and the conductive line are at different levels relative to the substrate.

In example embodiments, the bit line and the conductive line extend in different directions.

In example embodiments, the conductive line includes: a first conductive line disposed at the same level as that of the bit line; and a second conductive line disposed at a different level from that of the bit line.

In example embodiments, the first conductive line extends in a direction that is the same as that of the bit line, and the second conductive line extends in a direction different from that of the bit line.

In example embodiments, the gate electrodes include a ground selection line (GSL), a word line and a string selection line (SSL) sequentially stacked from the top surface of the substrate in the vertical direction, and further comprise a separation layer pattern that cuts the SSL.

In example embodiments, the separation layer pattern cuts an upper portion of the channel adjacent to the SSL.

In example embodiments, the conductive line and the conductive pattern include a same metal.

According to example embodiments, there is provided a method of manufacturing a vertical memory device. In the method, a plurality of insulating interlayers and a plurality of sacrificial layers are formed alternately and repeatedly on a substrate. A plurality of first holes is formed through the insulating interlayers and the sacrificial layers. A plurality of channels is formed in the first holes. A plurality of second holes is formed through the insulating interlayers and the sacrificial layers, a second hole of the plurality of second holes surrounded by a plurality of the first holes. The sacrificial layers are replaced with gate electrodes. A plurality of CSL contacts is formed in the second holes. A bit line and a CSL line are formed, each of the bit line and the CSL line electrically connected to the channels and the CSL contacts, respectively.

In example embodiments, the first holes and the second holes are formed simultaneously.

In example embodiments, a separation layer pattern which extends partially through the insulating interlayers and the sacrificial layers is further formed before replacing the sacrificial layers with the gate electrodes.

According to example embodiments, there is provided a vertical memory device, comprising: a substrate; a channel positioned on, and orthogonal to, the substrate; and a conductive pattern parallel to the channel positioned on the substrate. The conductive pattern has a shape that is substantially the same as a shape of the channel. The vertical memory device further comprises a bit line electrically connected to the channel and a conductive line at an upper portion of the vertical memory device. The conductive line is electrically connected to the conductive pattern.

In example embodiments, the vertical memory device further comprises at least one gate electrode surrounding an outer sidewall of the channel and the conductive pattern.

In example embodiments, the conductive pattern is a common source line (CSL) contact and the conductive line is a CSL.

In example embodiments, the bit line and the conductive line are at different levels relative to the substrate.

In example embodiments, the conductive line includes: a first conductive line disposed at the same level as that of the bit line; and a second conductive line disposed at a different level from that of the bit line.

According to example embodiments, a vertical memory device may include a conductive pattern having a shape substantially the same as or similar to that of a channel. The conductive pattern may be electrically connected to a conductive line disposed at an upper portion of the vertical memory device to be provided as a common source line contact. Thus, a trench or an opening cutting word lines and/or insulating interlayers may not be formed in order to form a common source line. Therefore, an area or a space for a formation of the channel may be additionally achieved. Additionally, the conductive pattern may be formed by processes substantially the same as or similar to those for the channel, so that an overall process for manufacturing the vertical memory device may be simplified.

### BRIEF DESCRIPTION OF THE DRAWINGS

Example embodiments will be more clearly understood from the following detailed description taken in conjunction with the accompanying drawings. FIGS. 1 to 28 represent non-limiting, example embodiments as described herein.

FIG. 1 is a perspective view illustrating a vertical memory device in accordance with example embodiments;

FIG. 2A is a top plan view illustrating the vertical memory device of FIG. 1;

FIG. 2B is a cross-sectional view taken along line I-I′ of FIG. 2A;

FIG. 3 is a cross-sectional view illustrating a vertical memory device of a comparative example;

FIGS. 4 to 17 are cross-sectional views illustrating a method of manufacturing a vertical memory device in accordance with some example embodiments;

FIGS. 18 to 21 are cross-sectional views illustrating a method of manufacturing a vertical memory device in accordance with some example embodiments;

FIGS. 22A to 22C are cross-sectional views illustrating vertical memory devices and methods of manufacturing the vertical memory devices in accordance with some example embodiments;

FIGS. 23A and 23B are a top plan view and a cross-sectional view, respectively, illustrating a vertical memory device in accordance with some example embodiments;

FIGS. 24 to 27 are cross-sectional views illustrating a method of manufacturing the vertical memory device of FIGS. 23A and 23B; and

FIG. 28 is a block diagram illustrating a schematic construction of an information processing system in accordance with example embodiments.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to obtain a vertical memory device having a high degree of integration, a density of the channels in a unit area at the device may be increased.

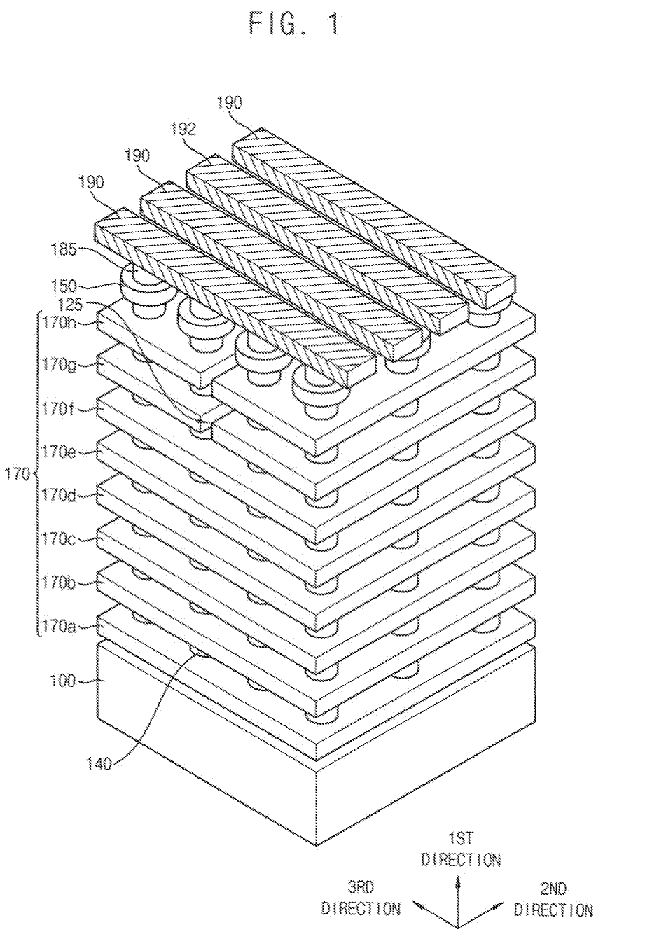

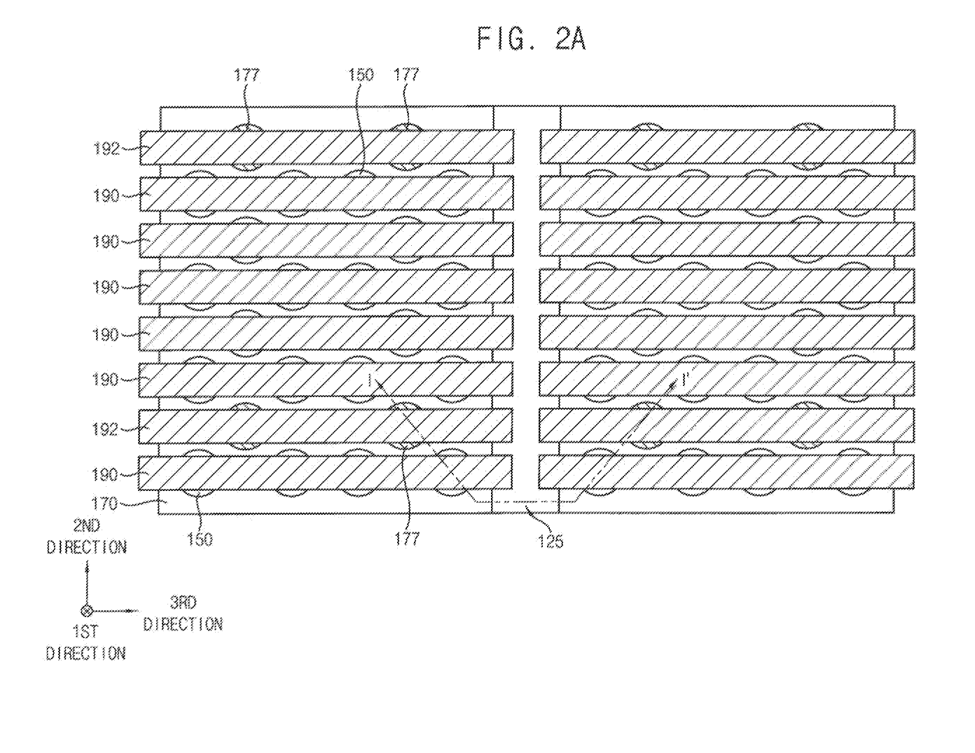

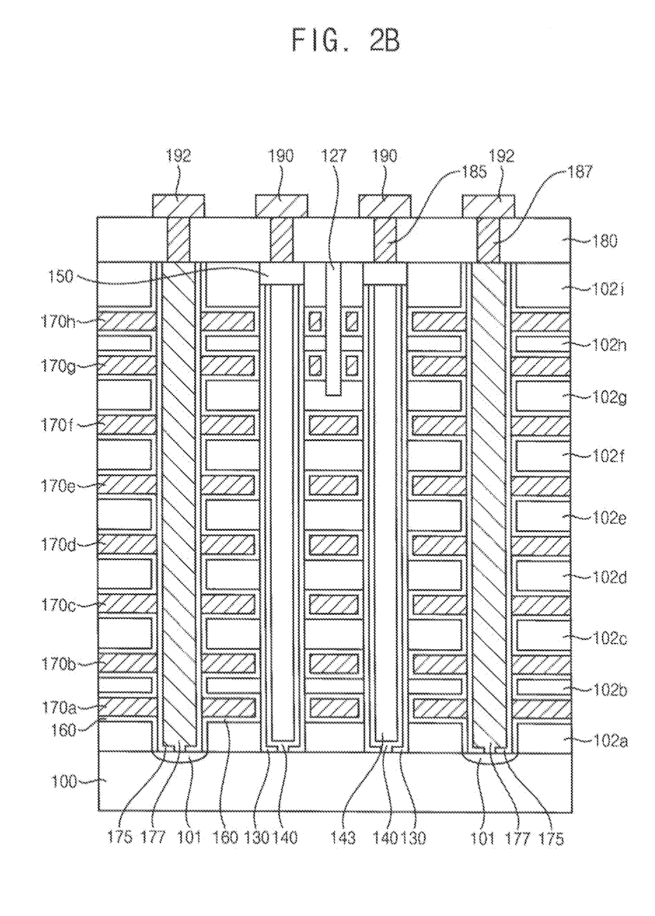

FIG. 1 is a perspective view illustrating a vertical memory device in accordance with example embodiments. FIG. 2A is a top plan view illustrating the vertical memory device of FIG. 1. FIG. 2B is a cross-sectional view taken along line I-I′ of FIG. 2A.

For reasons related to brevity, FIGS. 1 and 2A do not show all elements of the vertical semiconductor device, but only shows some elements thereof, e.g., a substrate, a channel, a gate electrode, a pad, a conductive pattern, a bit line contact and a bit line.

In the figures cited in this specification, a direction substantially perpendicular to a top surface of the substrate is referred to as a first direction, and two directions substantially parallel to the top surface of the substrate and substantially perpendicular to each other are referred to as a second direction and a third direction. Additionally, a direction indicated by an arrow in the figures and a reverse direction thereto are considered to be the same direction.

Referring to FIGS. 1, 2A and 2B, the vertical memory device may include a substrate 100 and a plurality of channels 140 and conductive patterns 177 protruding vertically from a top surface of the substrate 100. Gate electrodes 170 may at least partially surround the channel 140 and the conductive pattern 177 on outer sidewalls of the channel 140 and the conductive pattern 177, respectively. The gate electrodes 170 may be repeatedly stacked in the first direction spaced apart from each other. A pad 150 may be disposed on the channel 140. A bit line contact 185 contacting the pad 150 and a bit line 190 electrically connected to the bit line contact 185 may be disposed at an upper portion of the vertical memory device. The vertical memory device may include a conductive line 192 electrically connected to the conductive patterns 177. The conductive line 192 may be disposed at the upper portion of the vertical memory device. In example embodiments, the conductive line 192 and the bit line 190 may extend in the same direction, for example, in the third direction. The first, second, and/or third directions may be orthogonal to each other.

The substrate 100 may include a semiconductor material such as silicon or germanium, or the like.

The channel 140 may have a substantially hollow cylindrical shape or a substantially cup shape. A plurality of the channels 140 may be arranged along the second direction to form a channel column. A plurality of the channel columns may be arranged along the third direction to form a channel array. The channel 140 may include polysilicon or single crystalline silicon, or the like.

A filling layer pattern 143 may be formed in the channel 140. The filling layer pattern 143 may have a substantially pillar shape or a substantially solid cylindrical shape. The filling layer pattern 143 may include an insulation material such as silicon oxide or the like.

In one example embodiment, the channel 140 may have a substantially pillar shape or a substantially solid cylindrical shape. In this case, the filling layer pattern 143 may be omitted.

Referring to FIG. 2B, a dielectric layer structure 130 may be formed on the outer sidewall of the channel 140. The dielectric layer structure 130 may have a cup shape of which a central bottom is opened.

The dielectric layer structure 130 may include a plurality of layers stacked in the third direction from the outer sidewall of the channel 140. In example embodiments, the dielectric layer structure 130 may include a tunnel insulation layer pattern, a charge storage layer pattern and a first blocking layer pattern. In one example embodiments, the first blocking layer pattern may be omitted.

In example embodiments, the first blocking layer pattern may include an oxide such as silicon oxide, the charge storage layer pattern may include a nitride such as silicon nitride or a metal oxide, and the tunnel insulation layer pattern may include an oxide such as silicon oxide. In one example embodiment, the dielectric layer structure 130 may have an oxide-nitride-oxide (ONO) layer structure.

The pad 150 may be formed on the filling layer pattern 143, the channel 140 and the dielectric layer structure 130. Accordingly, the pad 150 may be electrically connected to the bit line 190 via the bit line contact 185. The pad 150 may serve as a source/drain region through which charges are moved or transferred to the channel 140. The pad 150 may include polysilicon or single crystalline silicon. The pad 150 may further include n-type impurities, for example, phosphorus (P) or arsenic (As).

The conductive pattern 177 may have a substantially pillar shape or a substantially solid cylindrical shape. In example embodiments, the conductive pattern 177 may include a conductive material, e.g., a metal, a metal nitride or a doped polysilicon.

As illustrated in FIG. 2B, an insulation layer pattern 175 may be formed on an outer sidewall of the conductive pattern 177. The insulation layer pattern 175 may surround the outer sidewall of the conductive pattern 177. The insulation layer pattern 175 may have a substantially cup shape and have a central bottom which is opened. In example embodiments, the insulation layer pattern 175 may include an insulation material, e.g., silicon oxide.

The conductive pattern 177 may be constructed and arranged to serve as a common source line (CSL) or a CSL contact of the vertical memory device. The number of the channels 170 disposed around one conductive pattern 177 may be determined according to a range in which the one conductive pattern 177 may function as a source region. In example embodiments, six channels 140 may be disposed around the one conductive pattern 177 to form a cell string block, as illustrated in FIG. 2A. In this case, the channels 140 may form a hexagonal array around the conductive pattern 177.

The number of the channels 140 included in the cell string block may be determined in consideration of an integration degree of the vertical memory device. For example, a cell string block may include the conductive pattern 177 at a central portion thereof. The cell string block may include 8, 12, 15 or 24 channels 140 around the conductive pattern 177. As the number of the channels 140 included in the cell string block is increased, a ratio of the number of the channels 140 to the number of the conductive patterns 177 may be increased. As the ratio is increased, the number of the channels 140 accommodated in a unit area of the substrate 100 may be increased so that a density or the integration degree of the vertical memory device may be improved.

In example embodiments, the conductive pattern 177 may have a width or a diameter substantially the same as that of the channel 140. Alternatively, the conductive pattern 177 may have a width or a diameter that is different from a width or diameter of the channel 140. For example, the width or the diameter of the conductive pattern 177 may be greater than that of the channel 140. As the width or the diameter of the conductive pattern 177 is increased, a distance within which the conductive pattern 177 may function as the source region may be increased so that the number of the channels 140 included in the cell string block may be increased. However, as the width or the diameter of the conductive pattern 177 is increased, a space, area, or related region for a formation of the channels 140 may be decreased. Thus, sizes and arrangements of the conductive patterns 177 and the channels 140 may be determined in consideration of the aforementioned trade-off.

As illustrated in FIG. 2B, an impurity region 101 may be formed at an upper portion of the substrate 100. The impurity region 101 is adjacent to, and in contact with, the conductive pattern 177. In example embodiments, the impurity region 101 may include n-type impurities such as phosphorus or arsenic. The impurity region 101 may have a substantially island shape formed on the substrate 100. The conductive pattern 177 may serve as a CSL contact that contacts the impurity region 101. In one example embodiment, a metal silicide pattern (not illustrated), e.g., a cobalt silicide pattern, may be formed between the impurity region 101 and the conductive pattern 177.

The gate electrodes 170 may be disposed on an outer sidewall of the dielectric layer structure 130, and spaced apart from each other in the first direction. In example embodiments, each gate electrode 170 may surround the channel 140 and may extend in the second direction and the third direction.

The gate electrode 170 may include a metal or a metal nitride. For example, the gate electrode 170 may include a metal having a low electrical resistance such as tungsten (W), tungsten nitride, titanium (Ti), titanium nitride, tantalum (Ta), tantalum nitride, platinum (Pt), etc. In one example embodiment, the gate electrode 170 may have a multi-layered structure including a barrier layer that may include the metal nitride. The multi-layered structure may further include a metal layer.

Two lowermost gate electrodes 170a and 170b may serve as ground selection lines (GSLs). Four gate electrodes 170c, 170d, 170e and 170f on the GSLs may serve as word lines. Two gate electrodes 170g and 170h on the word lines may serve as string selection lines (SSLs).

As described above, the GSLs, the word lines, and the SSLs may be formed at 2 levels, 4 levels and 2 levels, respectively. However, the number of levels at which the GSLs, the word lines and the SSLs are formed are not specifically limited. In some example embodiments, the GSL and the SSL may be formed at a single level, respectively, and the word lines may be formed at 2, 8 or 16 levels.

Insulating interlayers 102 may be disposed between the adjacent gate electrodes 170 in the first direction. The insulating interlayers 102 may include a silicon oxide based material, e.g., silicon dioxide (SiO₂), silicon carbooxide (SiOC) or silicon fluorooxide (SiOF). The gate electrodes 170 included in one cell string may be insulated from each other by the insulating interlayers 102.

In one example embodiment, a second blocking layer 160 may be formed on the insulating interlayers 102 and an outer sidewall of the dielectric layer structure 130 as illustrated in FIG. 2B. The second blocking layer 160 may include silicon oxide or a metal oxide. For example, the metal oxide may include aluminum oxide, hafnium oxide, lanthanum oxide, lanthanum aluminum oxide, lanthanum hafnium oxide, hafnium aluminum oxide, titanium oxide, tantalum oxide, zirconium oxide, etc. The second blocking layer 160 may include a multi-layered structure including but not limited to a silicon oxide layer and a metal oxide layer.

A separation region 125 may be provided between at least some of the channel columns neighboring each other to intersect or cut some of the gate electrodes 170 in the second direction. In example embodiments, the separation region 125 may serve as an SSL cut region. Two uppermost gate electrodes 170g and 170h serving as the SSLs may be cut by the separation region 125.

A separation layer pattern 127 may be formed in the separation region 125. The separation layer pattern 127 may include an insulation material, e.g., silicon oxide.

An upper insulation layer 180 may be formed on an uppermost insulating interlayer 102j, the pad 150, the conductive pattern 177 and the insulation layer pattern 175. The bit line contact 185 may be formed through the upper insulation layer 180 to contact the pad 150. A conductive line contact 187 may extend through the upper insulation layer 180 to contact the conductive pattern 177.

The bit line 190 may be disposed on the upper insulation layer 180 to be electrically connected to the bit line contact 185. A conductive line 192 may be disposed on the upper insulation layer 180 to be electrically connected to the conductive line contact 187. In example embodiments, a plurality of the bit line contacts 185 and a plurality of the conductive line contacts 187 may form arrays, which may be comparable to arrangements of the channels 140 and the conductive patterns 177, respectively.

In example embodiments, the conductive line 192, the conductive line contact 187 and the conductive pattern 177 may include the same material, e.g., the same metal as that of each other. Accordingly, resistances among the conductive line 192, the conductive line contact 187 and the conductive contact 177, respectively, may be minimized to increase an operation current.

The bit line 190 and the conductive line 192 may extend in substantially the same direction. FIG. 2A illustrates that the bit line 190 and the conductive line 192 may extend in the third direction, and that a plurality of the bit lines 190 and the conductive lines 192 may be arranged in the second direction. However, arrangements and configurations of the bit lines 190 and the conductive lines 192 shown in the figures are not specifically limited. For example, the bit line 190 and the conductive line 192 may extend in a direction oblique to the second and third directions by a predetermined angle.

The upper insulation layer 180 may include an insulation material, e.g., silicon oxide. The bit line contact 185, the bit line 190, the conductive line contact 187 and the conductive line 192 may include a conductive material, e.g., a metal, a metal nitride or doped polysilicon.

In example embodiments, the conductive line 192 may serve as a CSL of the vertical memory device. In this case, the conductive line contact 187 may serve as a CSL contact.

In one example embodiment, the bit line 190 and the conductive line 192 may be in direct contact with the pad 150 and the conductive pattern 177, respectively. Thus, the bit line contact 185 and the conductive line contact 187 may be omitted. In this case, the conductive pattern 177 may solely serve as the CSL contact.

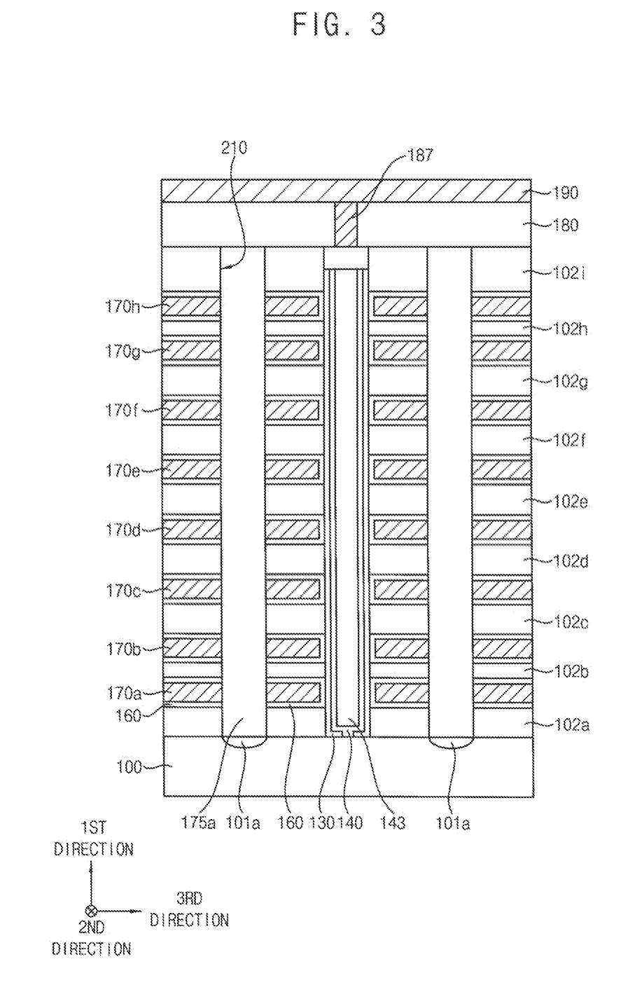

FIG. 3 is a cross-sectional view illustrating a vertical memory device of a comparative example. Detailed descriptions of elements and/or constructions substantially the same as or similar to those of the vertical memory device in accordance with example embodiments are omitted due to brevity. Like reference numerals are used to indicate like elements.

Referring to FIG. 3, an insulation layer pattern 175a may cut a plurality of gate electrodes 170a-h (generally, 170) along the first direction. The insulation layer pattern 175a may extend in the second direction (in and out of the page shown in FIG. 3). An impurity region 101a may be formed at an upper portion of a substrate 100 in contact with the bottommost insulation layer pattern 175a. The impurity region 101a may extend in the second direction and serve as a CSL of the vertical memory device of the comparative example.

Insulating interlayers 102a-i (generally, 102) and sacrificial layers (not illustrated) may be repeatedly stacked in the first direction. Channel holes (not illustrated) may be formed through the insulating interlayers 102 and the sacrificial layers. A dielectric layer structure 130, the channel 140 and a filling layer pattern 143 may be formed in a channel hole. Portions of the insulating interlayers 102 and the sacrificial layers between the adjacent channels 140 may be etched to form a trench 210. The trench 210 may extend in the second direction. A top surface of the substrate 100 may be exposed by the trench 210. Impurities may be implanted into the substrate 100 exposed by the trench 210 to form the impurity region 101a serving as the CSL. A silicide pattern may be optionally formed on the impurity region 101a. The sacrificial layers may be selectively removed. A second blocking layer 160 and the gate electrodes 170 may be formed in spaces from which the sacrificial layers are removed. The insulation layer pattern 175a may fill the trench 210 for positioning on the impurity region 101a.

According to the comparative example described above, the trench 210 may be formed in order to form the CSL and replace the sacrificial layers with gate electrodes 170. The trench 210 may be provided as an SSL cut region and a word line cut region. The impurity region 101a may have a linear shape that extends in the second direction.

According to example embodiments, a pillar-shaped conductive pattern 177 may be formed to fill a hole, and the CSL electrically connected to the conductive pattern 177 may be formed at an upper portion of the vertical memory device. Thus, in such embodiments, a formation of the word line cut region may not be required, and an area for the CSL may be removed from the substrate 100. Therefore, the number of the channels 140 formed on the substrate 100 may be increased so that an active region of the substrate 100 may be expanded. Further, a degree of integration of the vertical memory device may be improved.

According to example embodiments, the CSL may include a metal. Thus, the CSL may have a resistance lower than that of the case that the impurity region 101a serves as the CSL, so that a sufficient operation current may be obtained.

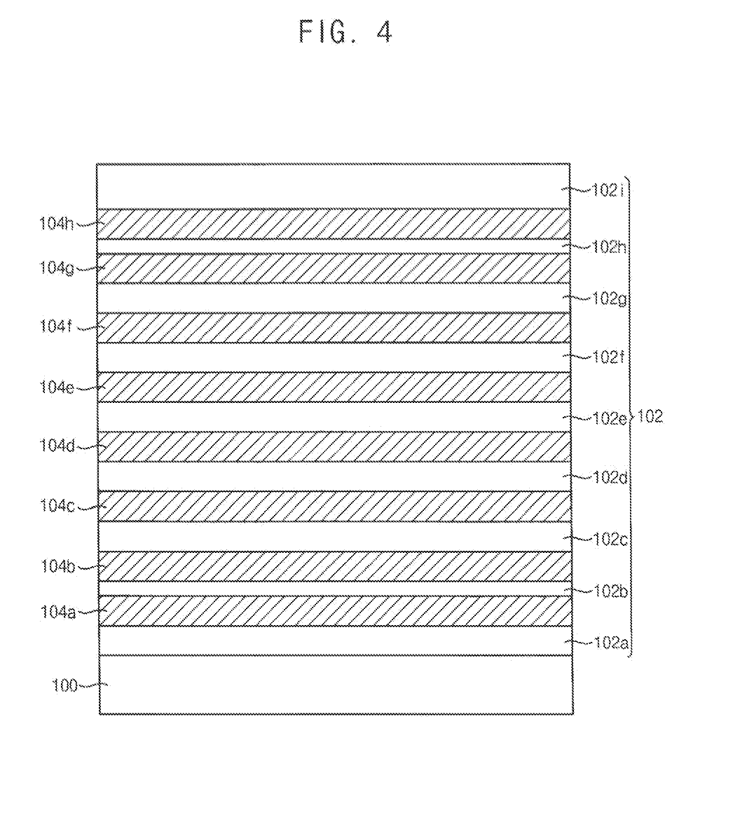

FIGS. 4 to 17 are cross-sectional views illustrating a method of manufacturing a vertical memory device in accordance with some example embodiments.

Referring to FIG. 4, an insulating interlayer 102 and a sacrificial layer 104 may be alternately and repeatedly formed on a substrate 100. A plurality of the insulating interlayers 102 and a plurality of the sacrificial layers 104 may be alternately formed on each other at a plurality of levels.

The substrate 100 may include a semiconductor material, e.g., single crystalline silicon and/or germanium.

In example embodiments, the insulating interlayer 102 may include a silicon oxide based material, e.g., silicon dioxide, silicon carbooxide or silicon fluorooxide. The sacrificial layer 104 may include a material having an etching selectivity with respect to the insulating interlayer 102 permitting the sacrificial layer 104 to be easily removed by a wet etching process. For example, the sacrificial layer 104 may be formed using a silicon nitride or silicon boronitride (SiBN).

The insulating interlayer 102 and the sacrificial layer 104 may be formed by a chemical vapor deposition (CVD) process, a plasma enhanced chemical vapor deposition (PECVD) process, an atomic layer deposition (ALD) process, etc. A lowermost insulating interlayer 102a may be formed by a thermal oxidation process on the substrate 100.

The sacrificial layers 104 may be removed in a subsequent process to provide spaces for a GSL, a word line and an SSL. Thus, the number of the insulating interlayers 102 and the sacrificial layers 104 may be adjusted in consideration of the number of the GSL, the word line and the SSL. In example embodiments, each of the GSL and the SSL may be formed at 2 levels, and the word line may be formed at 4 levels. Accordingly, the sacrificial layers 104 may be formed at 8 levels, and the insulating interlayers 102 may be formed at 9 levels. In another example embodiment, each of the GSL and the SSL may be formed at a single level, and the word line may be formed at 2, 8 or 16 levels. In this case, the sacrificial layers 104 may be formed at 4, 10 or 18 levels, and the insulating interlayers 102 may be formed at 5, 11 or 19 levels. However, the number of the GSL, the SSL and the word lines may not be limited to the examples provided herein.

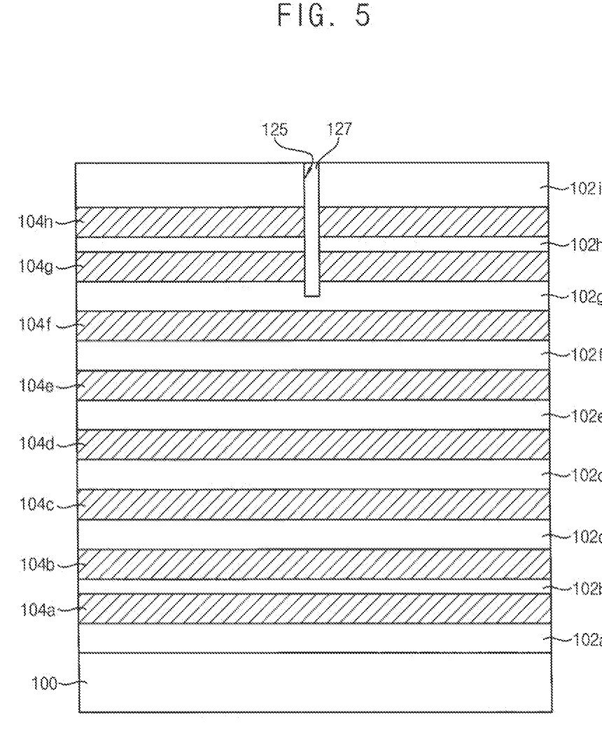

Referring to FIG. 5, a separation region 125 may be formed partially through the insulating interlayers 102 and the sacrificial layers 104, and a separation layer pattern 127 may be formed that partially or completely fills the separation region 125.

In example embodiments, the separation region 125 may be formed, by a photolithography process or the like to extend through the sacrificial layers 104, which are replaced with the SSL. For example, the separation region 125 may extend through an uppermost insulating interlayer 102i and two uppermost sacrificial layers 104h and 104g. The separation region 125 may further extend partially through an insulating interlayer 102g directly under the sacrificial layer 104g. The separation region 125 may also extend in the second direction.

A separation layer may be formed on the uppermost insulating interlayer 102i. The separation layer may sufficiently fill the separation region 125. An upper portion of the separation layer may be planarized until a top surface of the uppermost insulating interlayer 102i is exposed to form the separation layer pattern 127. In example embodiments, the separation layer may include an insulation material that may have an etching selectivity with respect to that sacrificial layer 104. For example, the separation layer may include silicon oxide by, e.g., a CVD process or a PECVD process. The planarization process may include a chemical mechanical polish (CMP) process and/or an etch-back process.

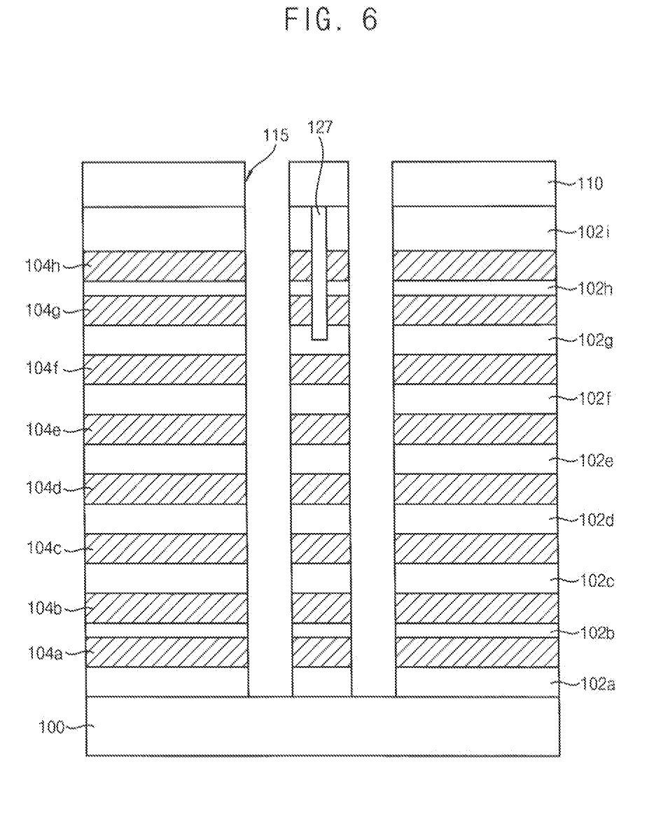

Referring to FIG. 6, a first hole 115 may be formed through the insulating interlayers 102 and the sacrificial layers 104, respectively.

In example embodiments, a hard mask 110 may be formed on the uppermost insulating interlayer 102i. The insulating interlayers 102 and the sacrificial layers 104 may be partially etched by performing a dry etching process or the like. In doing so, the hard mask 110 may be used as an etching mask to form the first hole 115. A top surface of the substrate 100 may be partially exposed by the first hole 115. The first hole 115 may extend in the first direction from the top surface of the substrate 100.

The hard mask 110 may include a material that may have an etching selectivity with respect to the insulating interlayers 102 and the sacrificial layers 104. For example, the hard mask 110 may include polysilicon or amorphous silicon.

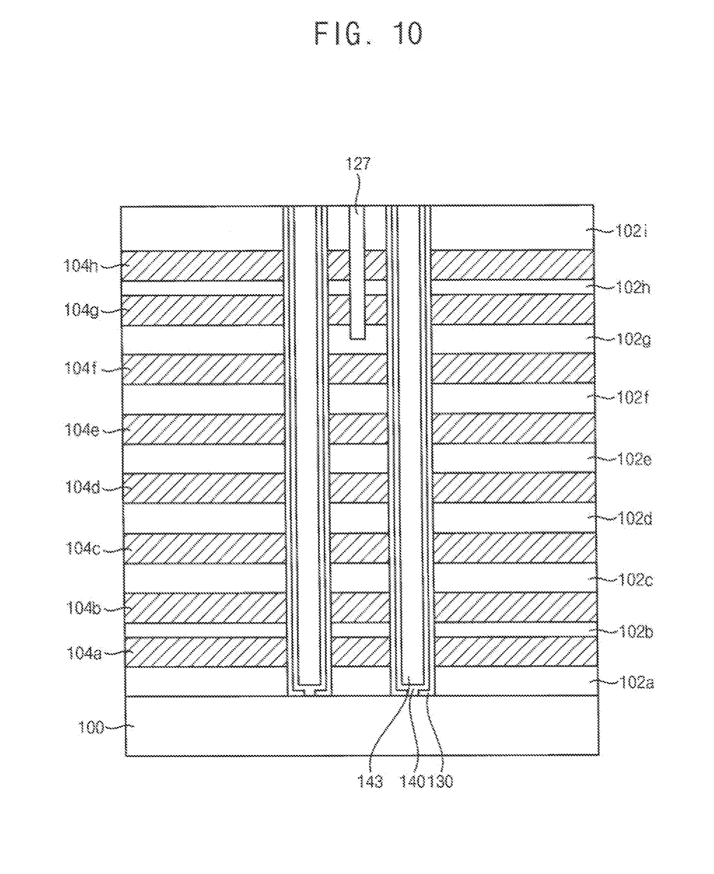

A channel 140 (refer to FIG. 10) may be formed in the first hole 115. Thus, a plurality of the first holes 115 may be arranged in a regular uniform arrangement, such as an array or other arrangement of rows and columns, or randomly, in the second and third directions.

In example embodiments, the first holes 115 may form a zigzag arrangement so that the number of the channels 140 accommodated in a unit area of the substrate 100 may be increased. For example, a first plurality of the first holes 115 may be formed in the second direction to form a first column, and a second plurality of the first holes 115 may be formed in a direction oblique to the second direction by a predetermined acute angle to form a second column (refer to the arrangement of the pads 150 illustrated in FIG. 2A).

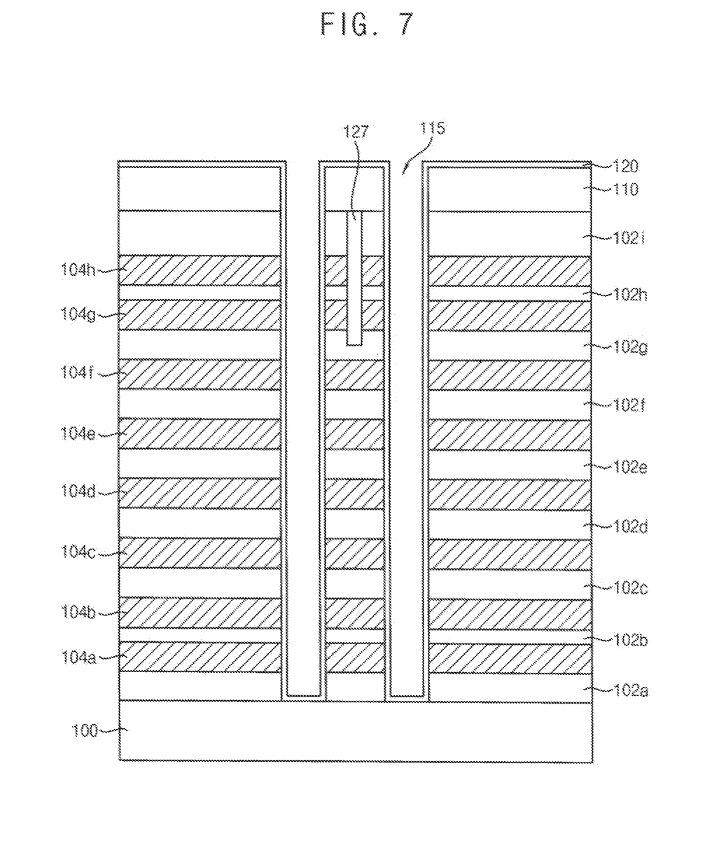

Referring to FIG. 7, a dielectric layer 120 may be formed on a sidewall and a bottom of the first holes 115 and on the hard mask 110.

In example embodiments, a first blocking layer, a charge storage layer and a tunnel insulation layer may be sequentially formed to obtain the dielectric layer 120.

In example embodiments, the first blocking layer may include an oxide, e.g., silicon oxide, the charge storage layer may include silicon nitride or a metal oxide, and the tunnel insulation layer may include an oxide, e.g., silicon oxide. In one example embodiment, the dielectric layer 120 may have an oxide-nitride-oxide (ONO) layer structure. The first blocking layer, the charge storage layer and the tunnel insulation layer may be formed by a CVD process, a PECVD process, an ALD process, etc. In one example embodiment, the formation of the first blocking layer may be omitted.

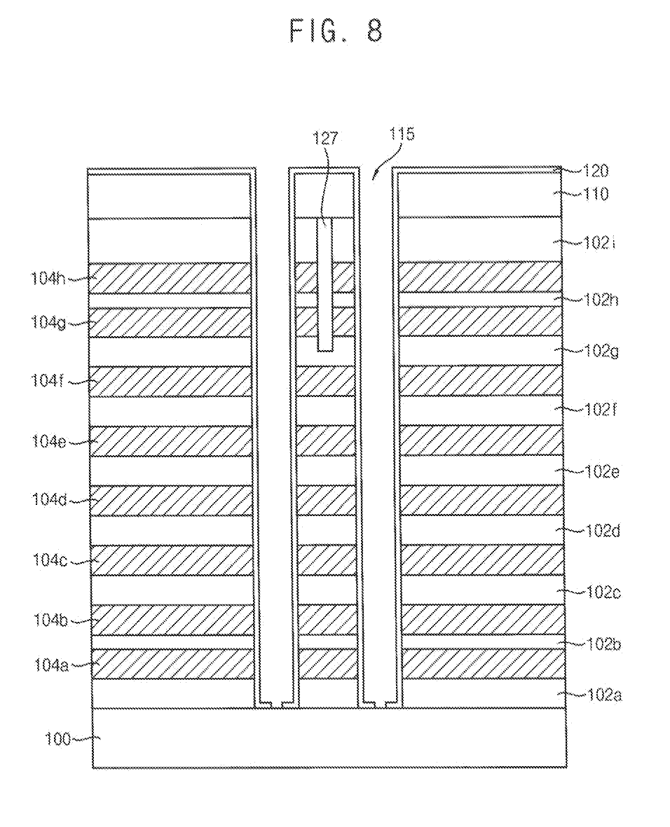

Referring to FIG. 8, a portion of the dielectric layer 120 which is formed on the bottom of the first hole 115 may be partially etched to expose the top surface of the substrate 100. Accordingly, a central bottom of the dielectric layer 120 may include an opening in the first hole 115 to expose a top surface of the substrate 100.

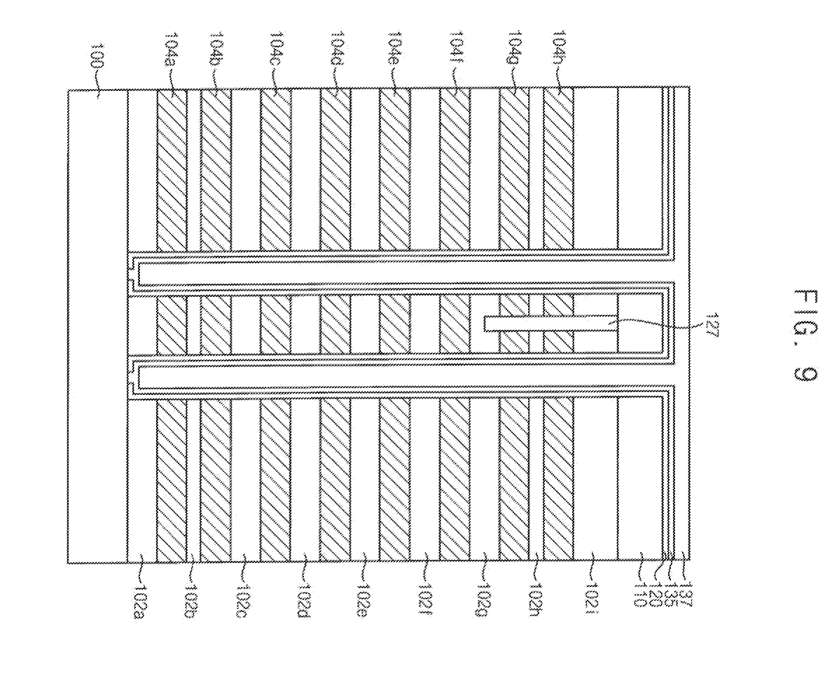

Referring to FIG. 9, a channel layer 135 may be formed on the dielectric layer 120 and the exposed top surface of the substrate 100A filling layer 137 may be formed on the channel layer 135 to sufficiently fill, i.e., partially or completely fill, a remaining portion of the first hole 115. The channel layer 135 may include polysilicon or amorphous silicon. The filling layer 137 may include an insulation material, e.g., silicon oxide or silicon nitride. In one example embodiment, a heat treatment or a laser beam irradiation may be further performed on the channel layer 135. In this case, the channel layer 135 may include single crystalline silicon and defects in the channel layer 135 may be cured.

The channel layer 135 and the filling layer 137 may be obtained by a CVD process, a PECVD process, an ALD process, and so on.

In one example embodiment, the channel layer 135 may be formed to fill the first hole 115. In this case, the formation of the filling layer 137 may be omitted.

Referring to FIG. 10, the filling layer 137, the channel layer 135, the dielectric layer 120 and the hard mask 110 may be planarized until the top surface of the uppermost insulating interlayer 102i is exposed to form a dielectric layer structure 130, the channel 140 and a filling layer pattern 143 sequentially stacked in the first hole 115. The planarization process may include an etch-back process or a CMP process.

In example embodiments, the dielectric layer structure 130 may have a substantially hollow cylindrical shape or a straw shape. The channel 140 may have a substantially cup shape. The filling layer pattern 143 may have a substantially solid cylindrical shape or a substantially pillar shape.

In embodiments where the channel layer 135 fully fills the first hole 115, the filling layer pattern 143 may be omitted and the channel 140 may have a substantially solid cylindrical shape or a substantially pillar shape.

A channel array having a zigzag arrangement may be formed according to a layout and arrangement of the first holes 115.

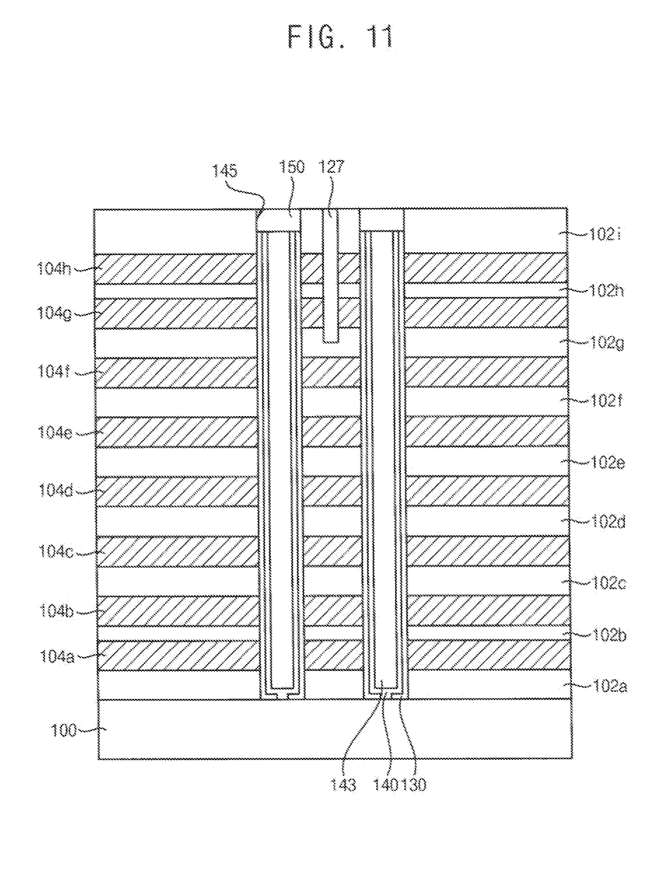

Referring to FIG. 11, upper portions of the dielectric layer structure 130, the channel 140 and the filling layer pattern 143 may be partially removed to form a recess 145. A pad 150 may be formed that caps or otherwise covers the recess 145.

In example embodiments, the upper portions of the dielectric layer structure 130, the channel 140 and the filling layer pattern 143 may be removed by an etch-back process to form the recess 145. In particular, a pad layer may be formed on the dielectric layer structure 130, the channel 140, the filling layer pattern 143 and the uppermost insulating interlayer 102i to sufficiently fill the recess 145. An upper portion of the pad layer may be planarized until the top surface of the uppermost insulating interlayer 102i is exposed to form the pad 150 from the remaining portion of the pad layer. In example embodiments, the pad layer may include polysilicon or doped polysilicon. In one example embodiment, a preliminary pad layer may include amorphous silicon, and then a crystallization process may be performed thereon to form the pad layer. The planarization process may include a CMP process or the like.

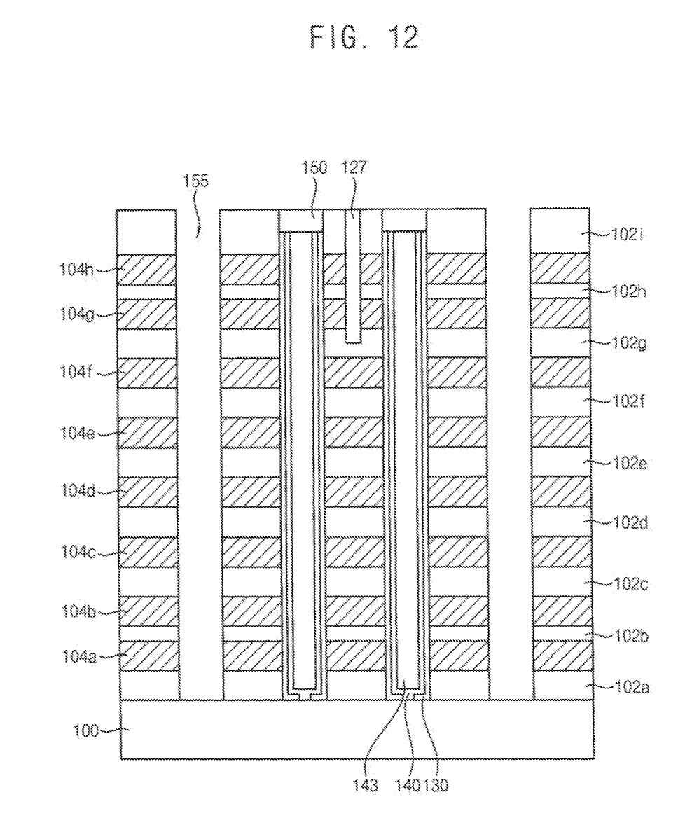

Referring to FIG. 12, a second hole 155 may be formed through the insulating interlayers 102 and the sacrificial layers 104. The top surface of the substrate 100 may be exposed by the second hole 155.

In example embodiments, a hard mask (not illustrated) may be formed on the uppermost insulating interlayer 102i. The insulating interlayers 102 and the sacrificial layers 104 may be partially etched by, e.g., a dry etching process using the hard mask as an etching mask to form the second holes 155.

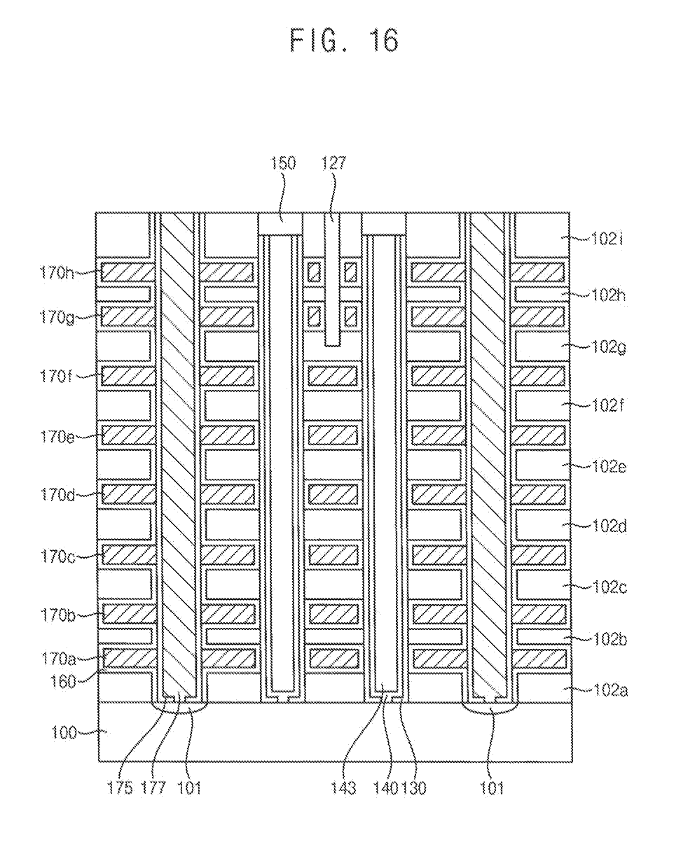

In example embodiments, the second hole 155 may provide a space for forming a conductive pattern 177 (refer to FIG. 16). In this case, the second hole 155 may be surrounded by a plurality of the channels 140. For example, six channels 140 may be positioned around one second hole 155. Alternatively, 8, 12, 15 or 24 channels 140 may be placed around one second hole 155.

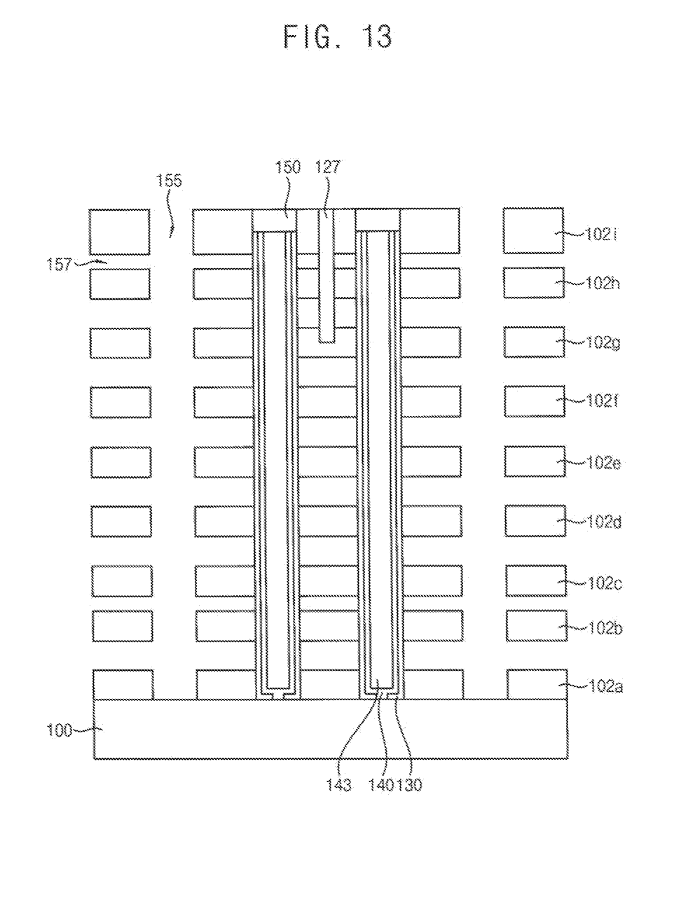

Referring to FIG. 13, the sacrificial layers 104, sidewalls of which are exposed by the second hole 155 may be removed. In example embodiments, the sacrificial layers 104 may be removed by a wet etching process using techniques, e.g., phosphoric acid and/or sulfuric acid as an etching solution.

A gap 157 may be defined by a region at which the sacrificial layer 104 is removed. A plurality of gaps 157 may be formed along the first direction. Each gap 157 may be formed between adjacent insulating interlayers 102. An outer sidewall of the dielectric layer structure 130 may be at least partially exposed by the gap 157.

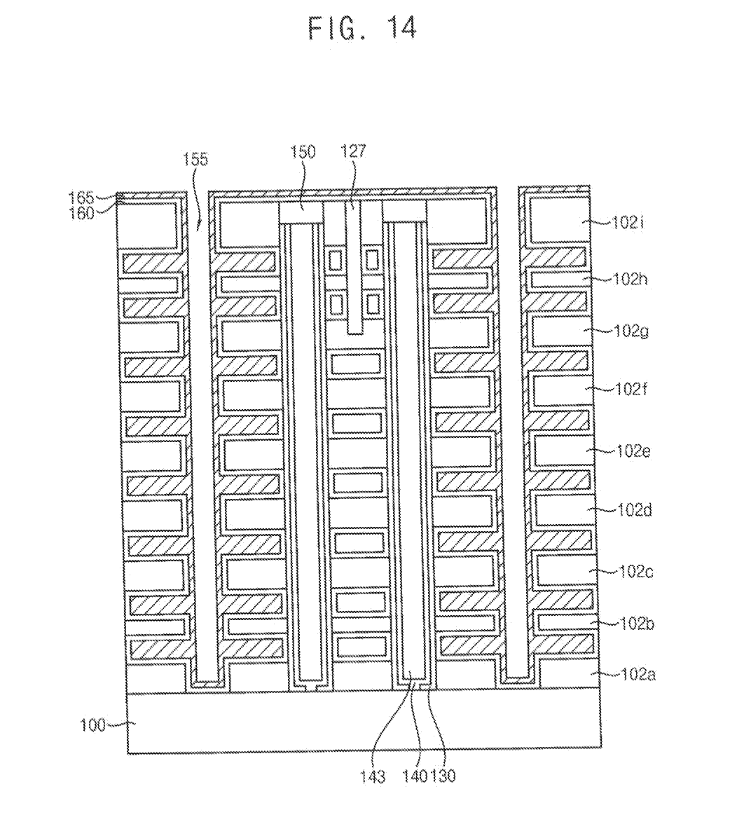

Referring to FIG. 14, a gate electrode layer 165 may be formed on the exposed outer sidewall of the dielectric layer structure 130, surfaces of the insulating interlayers 102, the exposed top surface of the substrate 100, a top surface of the pad 150 and a top surface of the separation layer pattern 127. In one example embodiment, a second blocking layer 160 may be further formed prior to forming the gate electrode layer 165. The gate electrode layer 165 may sufficiently fill the gaps 157 and at least partially fill the second hole 155.

The second blocking layer 160 may include, e.g., silicon oxide or a metal oxide. The metal oxide may include but not be limited to aluminum oxide, hafnium oxide, lanthanum oxide, lanthanum aluminum oxide, lanthanum hafnium oxide, hafnium aluminum oxide, titanium oxide, tantalum oxide or zirconium oxide. The second blocking layer 160 may be formed as a multi-layered structure including but not limited to a silicon oxide layer and a metal oxide layer.

The gate electrode layer 165 may include a metal or a metal nitride. For example, the gate electrode layer 165 may include but not be limited to tungsten, tungsten nitride, titanium, titanium nitride, tantalum, tantalum nitride, platinum, or the like. In one example embodiment, the gate electrode layer 165 may be formed as a multi-layered structure including a barrier layer that may include the metal nitride, and a metal layer.

The second blocking layer 160 and the gate electrode layer 165 may be formed by a CVD process, a PECVD process, an ALD process, a sputtering process, or other process.

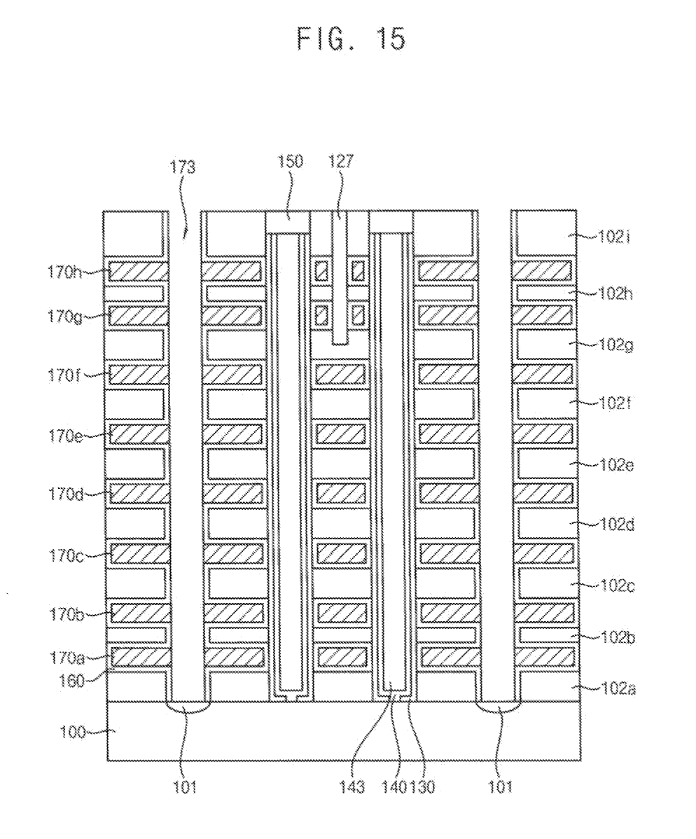

Referring to FIG. 15, the gate electrode layer 165 may be partially removed to form a gate electrode 170 in the gap 157 at each level.

For example, an upper portion of the gate electrode layer 165 may be planarized until the uppermost insulating interlayer 102i is exposed. A portion of the second blocking layer 160 formed on the uppermost insulating interlayer 102i, the pad 150, and the separation layer pattern 127 may also be removed during the planarization process. A portion of the gate electrode layer 165 formed in the second hole 155 may be etched to obtain the gate electrodes 170. A portion of the second blocking layer 160 which is formed on the top surface of the substrate 100 may also be removed during the etching process so that a third hole 173 exposing the top surface of the substrate 100 may be defined.

In example embodiments, the planarization process may include a CMP process. The etching process may include a wet etching process.

In one example embodiment, a portion of the second blocking layer 160 which is formed on sidewalls of the insulating interlayers 102 may also be removed during the etching process. In this case, a second blocking layer pattern may be formed on an inner wall of each gap 157 (see FIG. 13).

The gate electrodes 170 may include a GSL, a word line and an SSL, for example, described herein, which are sequentially stacked and spaced apart from one another in the first direction. For example, two lowermost gate electrodes 170a and 170b may serve as a GSL. Four gate electrodes 170c, 170d, 170e and 170f on the GSL may serve as a word line. Two gate electrodes on the word line 170g and 170h may serve as an SSL.

In example embodiments, the SSLs 170g and 170h may be adjacent to the separation layer pattern 127. In this case, the separation layer pattern 127 may serve as an SSL cut pattern. The word lines 170c, 170d, 170e and 170f, and the GSL 170a and 170b may extend in the second and third directions without being cut by the separation layer pattern 127.

In one example embodiment, impurities may be implanted through the top surface of the substrate 100 exposed by the third hole 173 to form an impurity region 101. The impurities may include n-type impurities such as phosphorus or arsenic. A metal silicide pattern, e.g., a cobalt silicide pattern or a nickel silicide pattern may be further formed on the impurity region 101. A plurality of the impurity regions 101 may be formed according to an arrangement of the third holes 173. Each impurity region 101 may have an island shape or the like.

Referring to FIG. 16, an insulation layer pattern 175 and a conductive pattern 177 may be formed in the third hole 173.

In example embodiments, an insulation layer may be formed on the uppermost insulating interlayer 102i, the pad 150 and the separation layer pattern 127, and on a sidewall and a bottom of the third hole 173. The insulation layer may include but not be limited to silicon oxide provided by a CVD process or an ALD process. A portion of the insulation layer formed on the bottom of the third hole 173 may be removed to expose the impurity region 101 or the top surface of the substrate 100.

A conductive layer may be formed on the insulation layer to fill a remaining portion of the third hole 173. In example embodiments, the conductive layer may include a metal, a metal nitride or doped polysilicon by, e.g., an ALD process or a sputtering process.

Upper portions of the conductive layer and the insulation layer may be planarized until the top surface of the uppermost insulating interlayer 102i is exposed to form the insulation layer pattern 175 and the conductive pattern 177 filling the third hole 173.

In example embodiments, the insulation layer pattern 175 may have a cup shape at which a central bottom is opened, or be of a straw shape. The conductive pattern 177 may have a pillar shape or a solid cylindrical shape. The conductive pattern 177 may serve as a CSL contact of the vertical memory device. In one example embodiment, the conductive pattern 177 may contact the impurity region 101.

As described herein with reference to FIG. 2A, a conductive pattern 177 and the channels 140 disposed around the conductive pattern 177 may form one cell string block. The number of the channels 140 included in the cell string block may be determined in consideration of an integration degree of the vertical memory device. For example, the cell string block may include the conductive pattern 177 at a central portion thereof, and further include about 6, 8, 12, 15 or 24 channels 140 around the conductive pattern 177. As the number of the channels 140 included in the cell string block is increased, a density or the integration degree of the vertical memory device may be improved.

The conductive pattern 177 may have a width or a diameter greater than that of the channel 140. As the width or the diameter of the conductive pattern 177 is increased, the number of the channels 140 within a source region created by the conductive pattern 177 may likewise be increased. A size and an arrangement of the conductive patterns 177 may be determined in consideration of the number of the channels 140 and a space available for the conductive pattern 177.

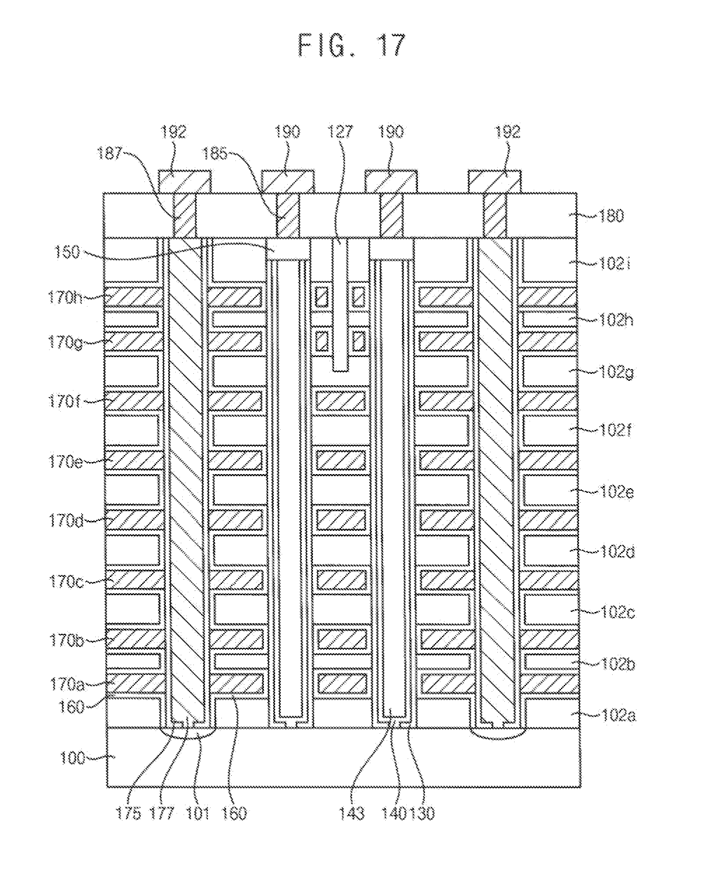

Referring to FIG. 17, an upper insulation layer 180 may be formed on the uppermost insulating interlayer 102i, the insulation layer pattern 175, the conductive pattern 177, the pad 150 and the separation layer pattern 127, respectively. The upper insulation layer 180 may include an insulation material such as silicon oxide by, e.g., a CVD process.

A bit line contact 185 and a conductive line contact 187 may be formed through the upper insulation layer 180 to abut and contact the pad 150 and the conductive pattern 177, respectively. The bit line contact 185 and the conductive line contact 187 may include a metal, a metal nitride or a doped polysilicon. In example embodiments, the bit line contact 185 and the conductive line contact 187 may be formed simultaneously.

A bit line 190 and a conductive line 192 may be formed on the upper insulation layer 180 to be electrically connected to the bit line contact 185 and the conductive line contact 187, respectively. The bit line 190 and the conductive line 192 may include a metal, a metal nitride or a doped polysilicon by, e.g., an ALD process or a sputtering process. The bit line 190 and the conductive line 192 may be formed simultaneously.

In example embodiments, the conductive line 192, the conductive line contact 187 and the conductive contact 177 may include the same metal. Thus, resistances among the conductive line 192, the conductive line contact 187 and the conductive contact 177 may be minimized to increase an operation current of the vertical memory device.

A plurality of bit line contacts 185 and a plurality of conductive line contacts 187 may form a contact array comparable to an arrangement of the pads 150 and the conductive pattern 177. The bit line 180 and the conductive line 192 may extend in the same direction, e.g., the third direction, for example, as illustrated in FIG. 2A. Alternatively, the bit line 190 and the conductive line 192 may extend in a direction oblique to the second and third directions by a predetermined angle.

In example embodiments, the conductive line 192 may serve as a CSL of the vertical memory device. In this case, the conductive line contact 187 and the conductive pattern 177 may serve as the CSL contact.

In one example embodiment, the bit line 190 and the conductive line 192 may directly contact the pad 150 and the conductive contact 177, respectively. In this case, the formation of the bit line contact 185 and the conductive line contact 187 may be omitted, and the conductive contact 177 may solely serve as the CSL contact.

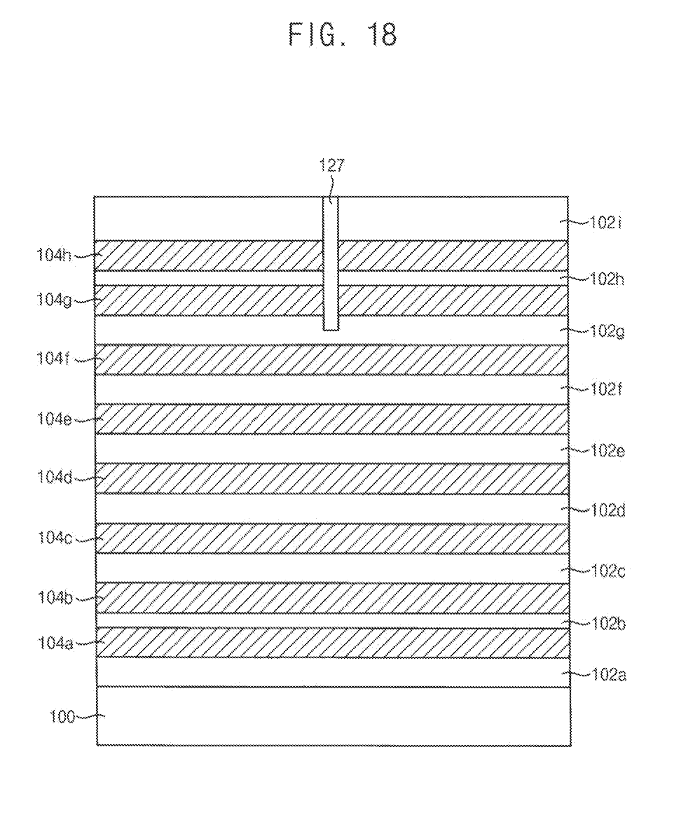

FIGS. 18 to 21 are cross-sectional views illustrating a method of manufacturing a vertical memory device in accordance with some example embodiments. Detailed descriptions on processes substantially the same as or similar to those illustrated with reference to FIGS. 4 to 17 may be omitted for brevity. Like reference numerals are used to indicate like elements.

Referring to FIG. 18, processes substantially the same as or similar to those illustrated with reference to FIGS. 4 and 5 may be performed. Accordingly, insulating interlayers 102a-102i (generally, 102) and sacrificial layers 104a-104h (generally, 104) may be formed alternately and repeatedly on a substrate 100. A separation layer pattern 127 may be formed partially through some of the insulating interlayers 102 and the sacrificial layers 104.

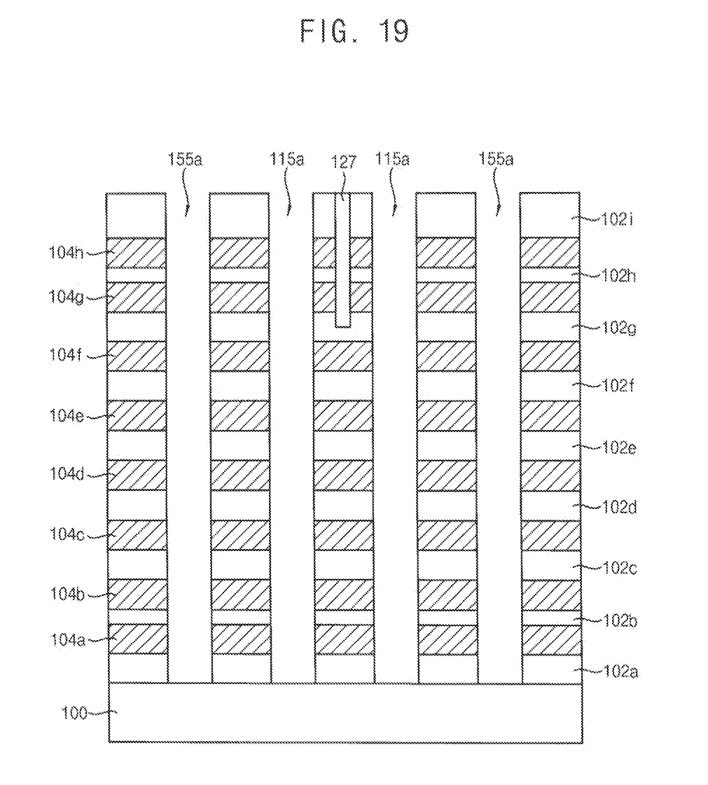

Referring to FIG. 19, a plurality of first and second holes 115a and 155a may be formed through the insulating interlayers 102 and the sacrificial layers 104.

The first holes 115a and the second holes 155a may be formed simultaneously. For example, the first holes 115a and the second holes 155a may be formed by a single dry etching process using a single etching mask. In this case, the first hole 115a and the second hole 155a may each have a diameter or a width the same as that of the other.

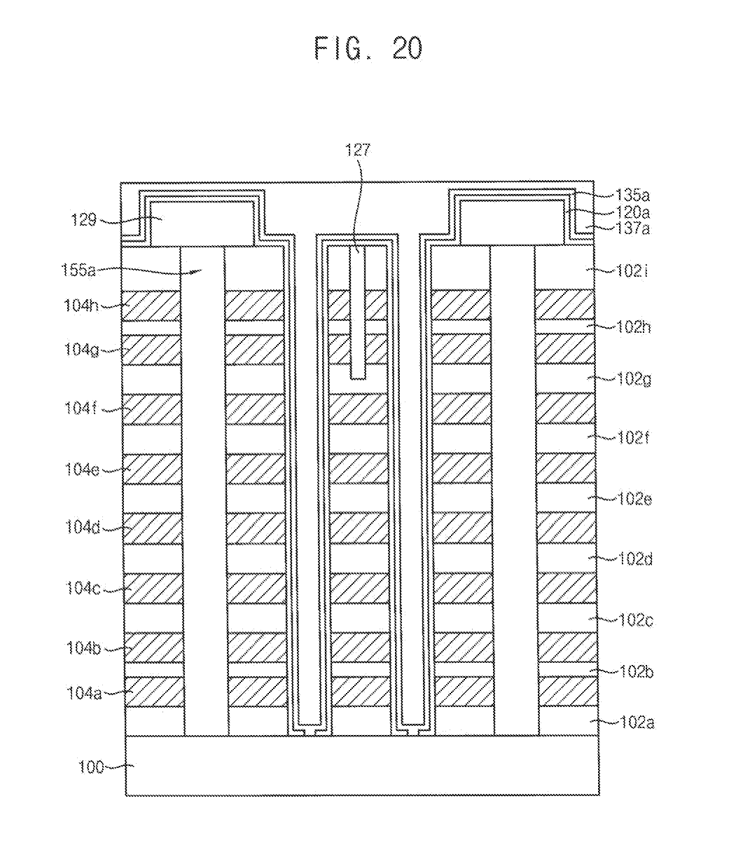

Referring to FIG. 20, a dielectric layer 120a, a channel layer 135a and a filling layer 137a filling the first hole 115a may be sequentially formed.

In example embodiments, a mask pattern 129 may be formed on an uppermost insulating interlayer 102i for capping an entrance of the second hole 155a. Processes substantially the same as or similar to those illustrated with reference to FIGS. 7 to 9 may be performed to form the dielectric layer 120a, the channel layer 135a and the filling layer 137a filling the first hole 115a on the uppermost insulating interlayer 102i, the mask pattern 129 and an inner wall of the first hole 115a.

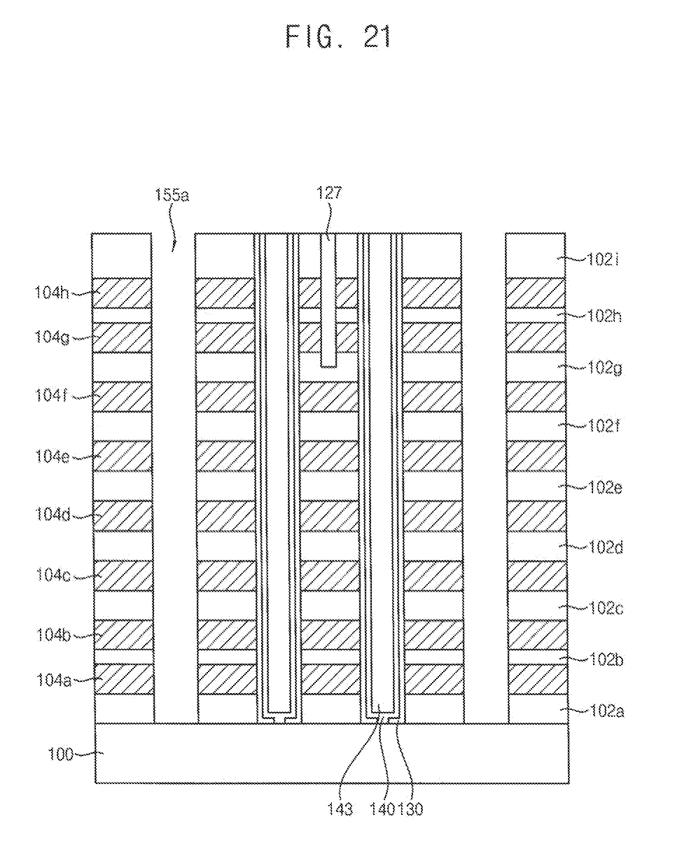

Referring to FIG. 21, a process substantially the same as or similar to that illustrated with reference to FIG. 10 may be performed to form a dielectric layer structure 130, a channel 140, and a filling layer pattern 143, respectively. For example, the dielectric layer 120a, the channel layer 135a and the filling layer 137a and the mask pattern 129 may be planarized until a top surface of the uppermost insulating interlayer 102i is exposed to obtain the dielectric layer structure 130, the channel 140 and the filling layer pattern 143. The planarization process may include a CMP process and/or an etch-back process.

Processes substantially the same as or similar to those illustrated with reference to FIGS. 11 to 17 may be further performed to obtain a vertical memory device according to example embodiments.

According to example embodiments describe above, the first hole 115a in which the channel 140 is formed and the second hole 155a in which the conductive pattern 177 is formed may be formed simultaneously by the same process, so that process costs and process time may be reduced.

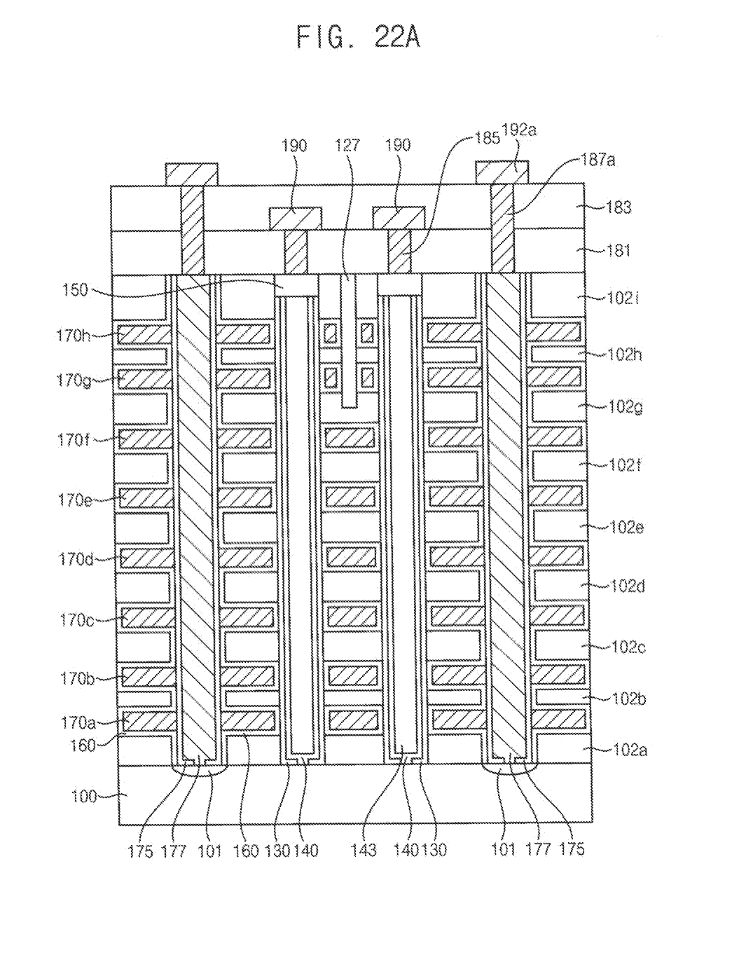

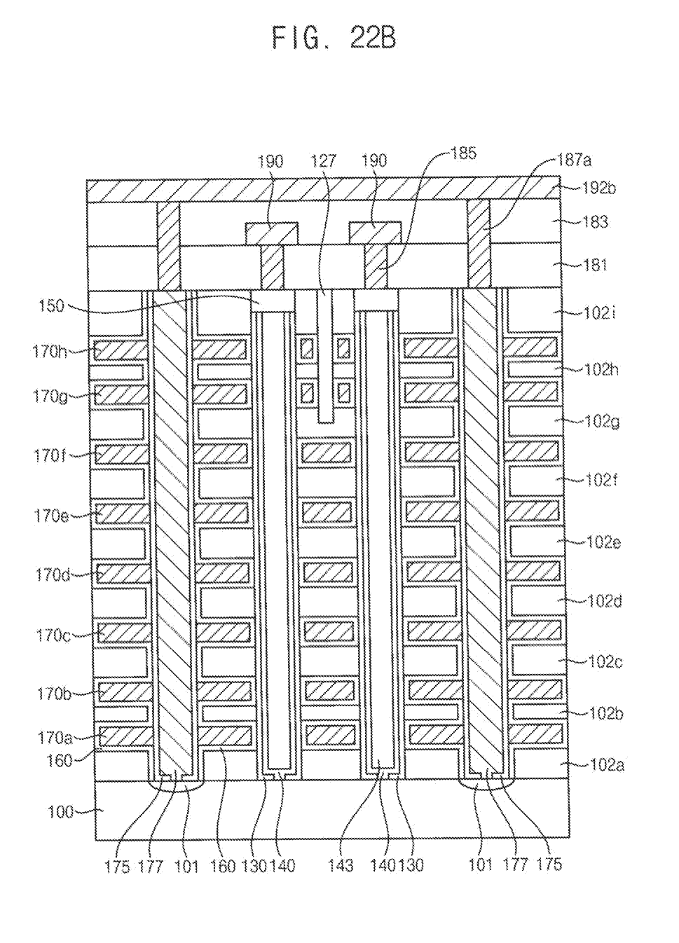

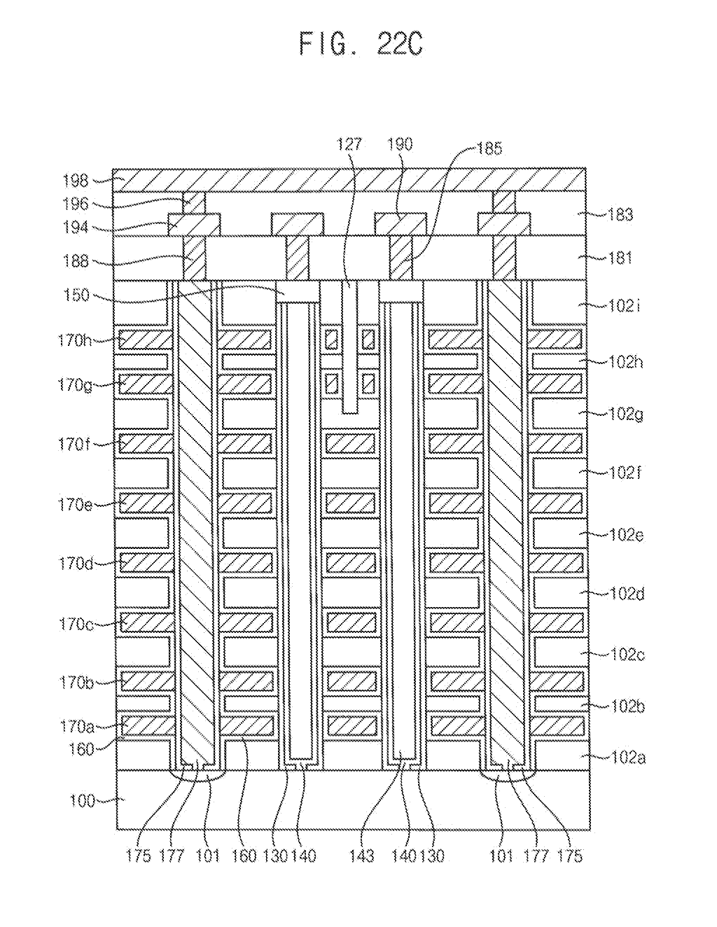

FIGS. 22A to 22C are cross-sectional views illustrating vertical memory devices and methods of manufacturing the vertical memory devices in accordance with some example embodiments. The vertical memory devices of FIGS. 22A to 22C may have constructions substantially the same as or similar to those illustrated FIGS. 1, 2A and 2B except for a different arrangement and a configuration of conductive lines. Thus, detailed descriptions on repeated elements and structures are omitted.

Referring to FIG. 22A, one or more bit lines 190 may be formed on a first upper insulation layer 181, and one or more conductive lines 192a may be formed on a second upper insulation layer 183.

For example, the first upper insulation layer 181 may be formed on an uppermost insulating interlayer 102i, a pad 150, a separation layer pattern 127, an insulation layer pattern 175 and a conductive pattern 177. A bit line contact 185 may be formed through the first upper insulation layer 181 to be in contact with the pad 150. The bit line 190 may be formed on the first upper insulation layer 181 to be electrically connected to the bit line contact 185. The second upper insulation layer 183 may be formed on the first upper insulation layer 181 to cover the bit line 190. The first and second upper insulation layers 181 and 183 may include, e.g., silicon oxide by a CVD process. A conductive line contact 187a may be formed through the second upper insulation layer 183 and the first upper insulation layer 181 to be in contact with the conductive contact 177. The conductive line 192a may be formed on the upper insulation layer 183 to be electrically connected to the conductive pattern 177 via the conductive line contact 187a.

According to some example embodiments described above, the conductive line 192a and the bit line 190 may be formed at different levels or on different layers. Thus, a space or an area for the formation of the bit lines 190 may be additionally achieved so that a pitch or a distance between the bit lines 190 may be reduced.

The conductive line 192a and the bit line 190 may extend in the same direction, e.g. the third direction as illustrated in FIG. 2A.

FIG. 22A illustrates that the conductive line 192a is placed over the bit line 190. Alternatively, the bit line 190 may be placed over the conductive line 192a. For example, the conductive line 192a may be formed on the first upper insulation layer 181, and the bit line 190 may be formed on the second upper insulation layer 183.

Referring to FIG. 22B, a conductive line 192b may be placed over a bit line 190 and extend in a different direction from a direction of extension of the bit line 190. For example, the bit line 190 may extend in the third direction on a first upper insulation layer 181, and the conductive line 192b may extend in the second direction on a second upper insulation layer 183.

In one example embodiment, the conductive line 192b may extend in a diagonal direction with respect to a direction of the bit line 190. In this case, the conductive line 192b may electrically connect conductive patterns 177 adjacent in the diagonal direction.

Referring to FIG. 22C, a conductive line may have a multi-stacked structure including a first conductive line 194 and a second conductive line 198.

For example, a first conductive line contact 188 and a bit line contact 185 may be formed through a first upper insulation layer 183 to contact a conductive pattern 177 and a pad 150, respectively. A first conductive line 194 and a bit line 190 may be disposed on the first upper insulation layer 181 to be electrically connected to the first conductive line contact 188 and the bit line contact 185, respectively. A second upper insulation layer 183 may be formed on the first upper insulation layer 181 to cover the first conductive line 194 and the bit line 190. A second conductive line contact 196 may be extend through the second upper insulation layer 183 to contact the first conductive line 194. A second conductive line 198 may be disposed on the second upper insulation layer 183 to be electrically connected to the first conductive line 194 via the second conductive line contact 196. One or more of the first conductive line contact 188, the second conductive line contact 196, the first conductive line 194, and the second conductive line 198 may include a conductive material including a metal, a metal nitride or doped polysilicon by an ALD process or a sputtering process. The first conductive line contact 188, the second conductive line contact 196, the first conductive line 194, and the second conductive line 198 may include the same conductive material.

In example embodiments, the first conductive line 194 and the bit line 190 may extend in substantially the same direction. The second conductive line 198 may extend in a different direction from that of the bit line 190. For example, the second conductive line 198 may extend in a direction substantially perpendicular or diagonal to that of the bit line 190.

FIG. 22C illustrates that the first conductive line 194 and the second conductive line 198 can be electrically connected to each other via the second conductive line contact 196. However, the second conductive line 198 may be electrically connected to the conductive pattern 177 via an additional conductive line contact that may be in direct contact with the conductive pattern 177 through the first and second upper insulation layers 181 and 183. In this case, the conductive patterns 177 may be divided into a first conductive pattern row, which is electrically connected to the first conductive line 194, and a second conductive pattern row, which is electrically connected to the second conductive line 198.

As described above, the conductive lines may be formed on at least two levels. Accordingly, that various constructions or designs of wirings may be achieved for the vertical memory device. Further, a density of the conductive patterns 177 and the channels 140 may be improved.

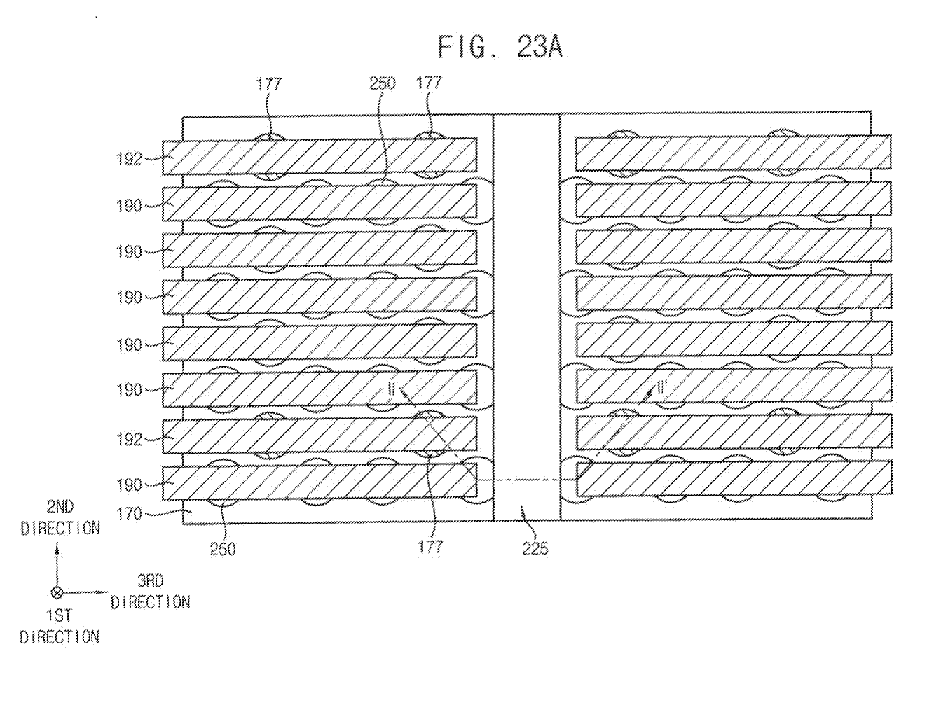

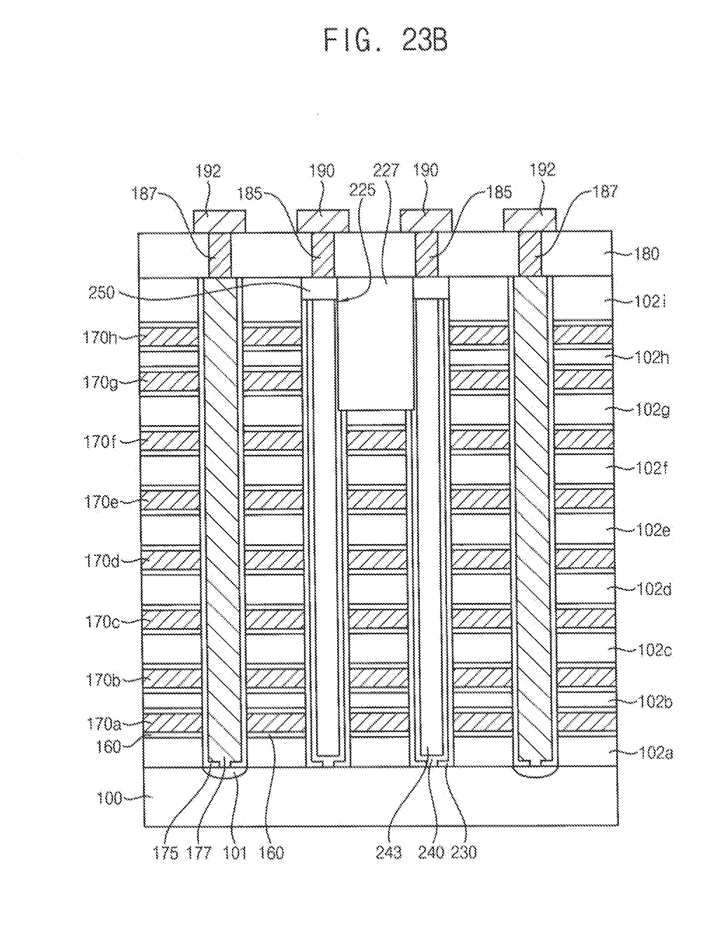

FIGS. 23A and 23B are a top plan view and a cross-sectional view, respectively, illustrating a vertical memory device in accordance with some example embodiments. Specifically, FIG. 23B is a cross-sectional view taken along a line II-IF of FIG. 23A.

The vertical memory device of FIGS. 23A and 23B may be constructed and arranged substantially the same as or similar to those illustrated with reference to FIGS. 1, 2A and 2B except for structures of a separation region and a separation pattern. Thus, detailed descriptions on repeated elements and structures are omitted. Like reference numerals are used to indicate like elements.

Referring to FIGS. 23A and 23B, a separation region 225 may be provided between at least some of the channel columns neighboring each other to cut gate electrodes 170 in the second direction. As described above, the separation region 225 may serve as an SSL cut region by which two uppermost gate electrodes 170g and 170h serving as the SSL may be cut. A separation layer pattern 227 including an insulation material, e.g., silicon oxide may be formed in the separation region.

In example embodiments, the separation layer pattern 227 may extend through lateral portions of the pad 250 and the channel 240. In this case, the channel 240 may have an undercut portion at a region in contact with the separation layer pattern 227. Thus, a thickness of the channel 240 at the region in contact with the separation layer pattern 227 may be decreased.

By forming the separation layer pattern 227 to at least partially cut the channel, a distance between the channel columns adjacent to the SSL cut region may be reduced. Thus, more channels 240 may be formed in a unit area of the substrate 100 so that a density or an integration degree of the vertical memory device may be additionally improved.

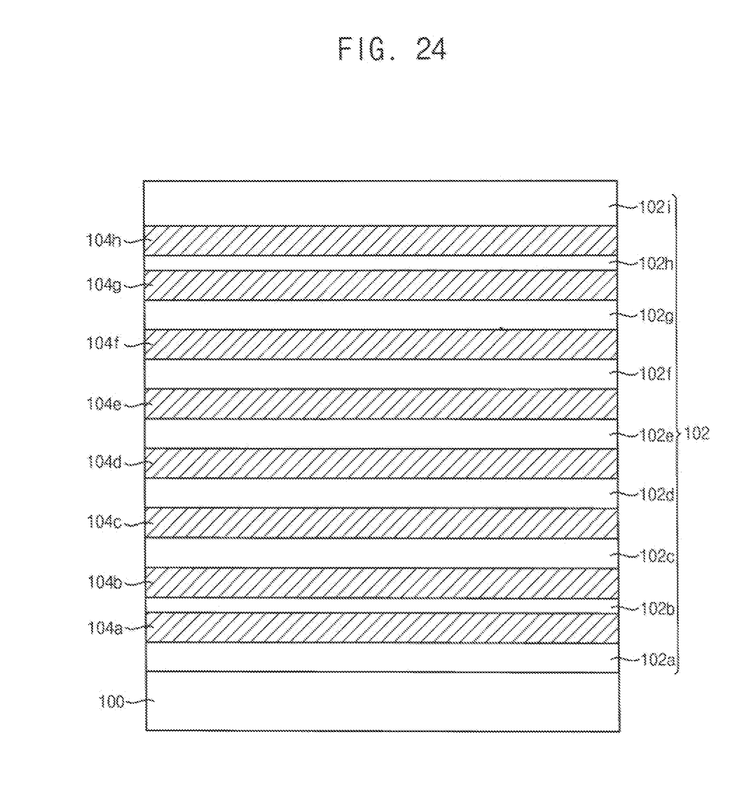

FIGS. 24 to 27 are cross-sectional views illustrating a method of manufacturing the vertical memory device of FIGS. 23A and 23B. Detailed descriptions on processes may be substantially the same as or similar to those illustrated with reference to FIGS. 4 to 17, and are omitted for brevity.

Referring to FIG. 24, a process substantially the same as or similar to that illustrated with reference to FIG. 4 may be performed to repeatedly and alternately form a plurality of insulating interlayers 102 and sacrificial layers 104.

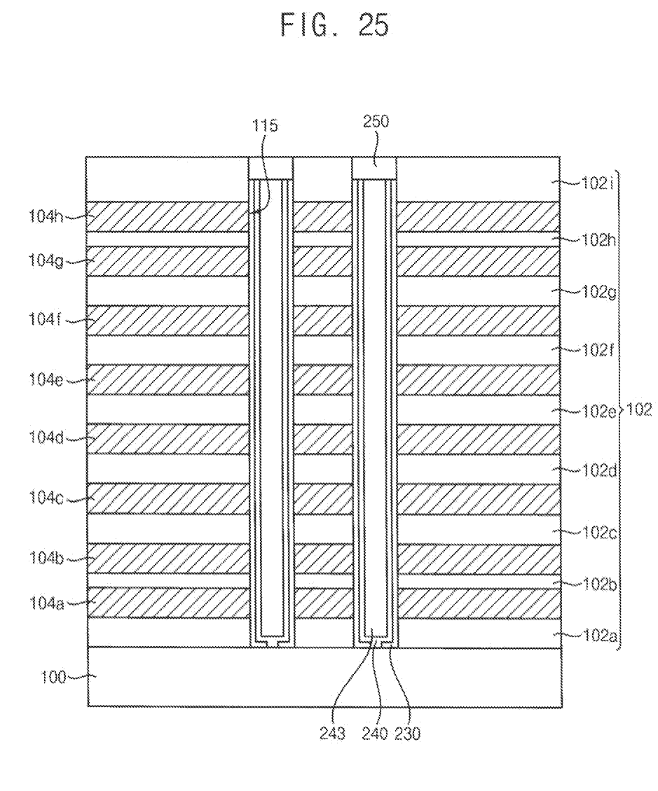

Referring to FIG. 25, processes substantially the same as or similar to those illustrated with reference to FIGS. 6 to 11 may be performed. Accordingly, a first hole 115 may be formed through the insulating interlayers 102 and the sacrificial layers 104 to expose a top surface of the substrate 100. A dielectric layer structure 230 may be formed on a sidewall of the first hole 115 and partially on a bottom of the first hole 115. A channel 240 may be formed on the dielectric layer structure 230 to contact the top surface of the substrate 100. A filling layer pattern 243 may be formed on the channel 240 to fill a remaining portion of the first hole 115. Upper portions of the dielectric layer structure 230, the channel 240 and the filling layer pattern 243 may be removed to form a recess. A pad filling the recess may be formed.

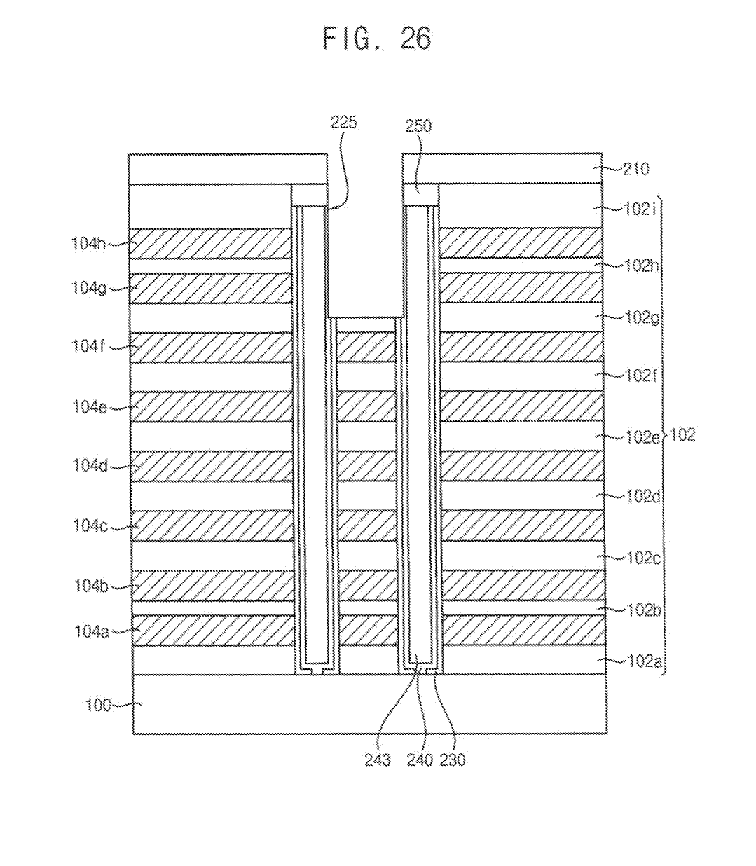

Referring to FIG. 26, a separation region 225 may be formed at least partially through the insulating interlayers 104 and the sacrificial layers 102. The separation region 225 may extend through lateral portions of the pads 250 and the channels 240 included in adjacent channel columns.

In example embodiments, a mask pattern 210 may be formed to cover portions of the pads 150 included in the channel columns. The mask pattern 210 may be formed on an uppermost insulating interlayer 102i. A dry etching process or an etch-back process may be performed using the mask pattern 210 as an etching mask to at least partially remove the uppermost insulating interlayer 102i, the sacrificial layers 104h and 104g, and the insulating interlayer 102g directly under the sacrificial layer 104g. The pads 250 and the dielectric layer structures 230 and the channels 240 may also be partially removed together with the insulating interlayers 102i, 102h and 102g, and the sacrificial layers 104g and 104h. The separation region 225 may have a trench shape extending in the second direction.

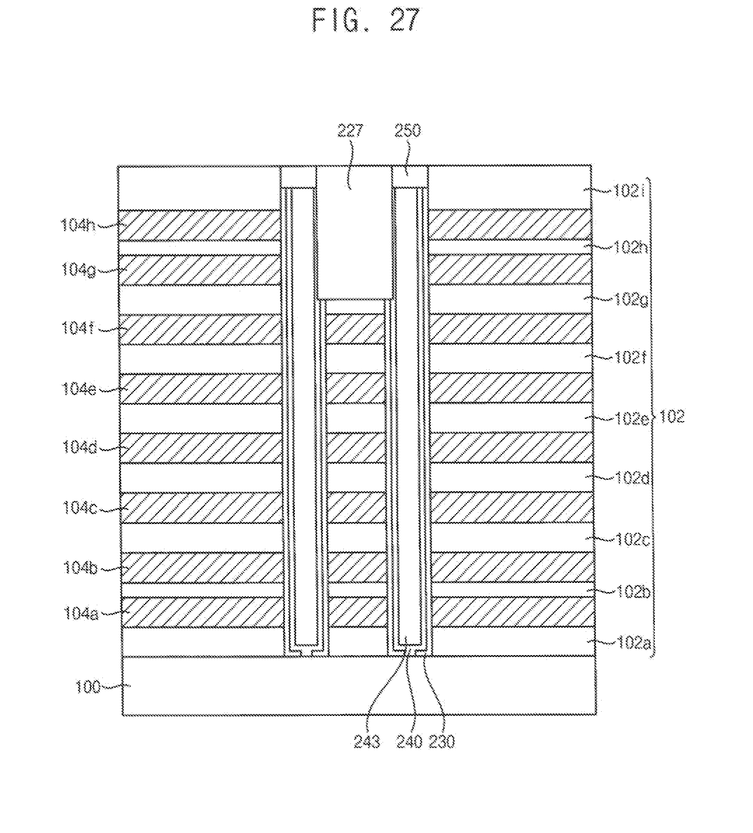

Referring to FIG. 27, a separation layer pattern 227 may be formed that fills the separation region 225.

In example embodiments, a separation layer may be formed on the mask pattern 210 that fills the separation region 225. The separation layer and the mask pattern 210 may be planarized until a top surface of the uppermost insulating interlayer 102i is exposed. The planarization process may include a CMP process or the like.

Subsequently, processes substantially the same as or similar to those illustrated with reference to FIGS. 12 to 17 may be performed to obtain the vertical memory device of FIGS. 23A and 23B.

The vertical memory device according to example embodiments may be implemented in various systems, e.g., those systems known to one or ordinary skill in the art such as an information processing system.

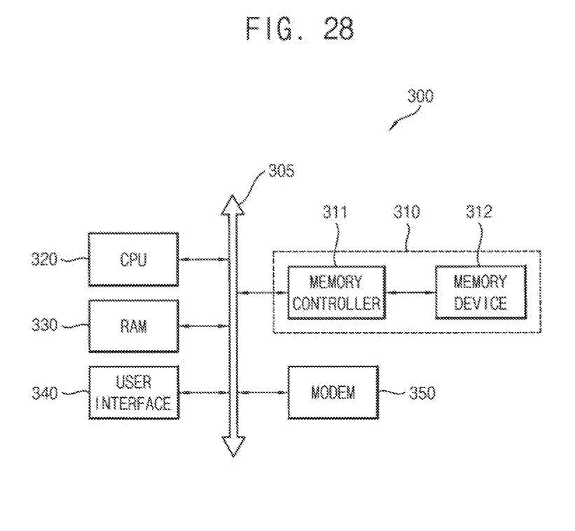

FIG. 28 is a block diagram illustrating a schematic construction of an information processing system in accordance with example embodiments.

Referring to FIG. 28, an information processing system 300 may include a CPU 320, a RAM 330, a user interface 340, a modem 350 such as a baseband chipset and a memory system 310 electrically connected to a system bus 305. The memory system 310 may include a memory device 312 and a memory controller 311. The memory device 312 may include the vertical memory device according to example embodiments. Thus, large data processed by the CPU 320 or input from an external device may be stored in the memory device 312 with high stability. The memory controller 311 may have a construction capable of controlling the memory device 312. The memory system 310 may be provided as, e.g., a memory card or a solid state disk (SSD) by a combination of the memory device 312 and the memory controller 311. In a case that the information processing system 300 is utilized for a mobile device, a battery may be further provided for supplying an operation voltage of the information processing system 300. The information processing system 300 may further include an application chipset, a camera image processor (CIS), a mobile DRAM, etc.

According to example embodiments of the present invention, a word line cut region or a CSL formed on a substrate may be removed or omitted from a vertical memory device, such that an increased number of memory cells may be integrated in a unit chip. Therefore, the vertical memory device may be efficiently utilized for a non-volatile memory device having high capacity and integration degree.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A vertical memory device, comprising:
a plurality of channels and conductive patterns extending in a vertical direction from a top surface of a substrate;
a plurality of gate electrodes surrounding outer sidewalls of the channels and the conductive patterns, the gate electrodes stacked in the vertical direction to be spaced apart from each other;
a bit line electrically connected to the channels; and
a conductive line electrically connected to the conductive patterns.

2. The vertical memory device of claim 1, wherein the conductive line is a common source line (CSL), and the conductive pattern is a CSL contact.

3. The vertical memory device of claim 2, further comprising an impurity region at an upper portion of the substrate in contact with the conductive pattern.

4. The vertical memory device of claim 1, wherein two or more of the plurality of the channels are disposed around one of the conductive patterns to form a cell string block.

5. The vertical memory device of claim 1, further comprising a dielectric layer structure between the channel and the gate electrodes, the dielectric layer structure extending from the top surface of the substrate in the vertical direction.

6. The vertical memory device of claim 1, wherein the bit line and the conductive line are at different levels relative to the substrate.

7. The vertical memory device of claim 6, wherein the bit line and the conductive line extend in different directions.

8. The vertical memory device of claim 1, wherein the conductive line includes:
a first conductive line disposed at the same level as that of the bit line; and
a second conductive line disposed at a different level from that of the bit line.

9. The vertical memory device of claim 8, wherein the first conductive line extends in a direction that is the same as that of the bit line, and the second conductive line extends in a direction different from that of the bit line.

10. The vertical memory device of claim 1, wherein the gate electrodes include a ground selection line (GSL), a word line and a string selection line (SSL) sequentially stacked from the top surface of the substrate in the vertical direction, and further comprising a separation layer pattern that cuts the SSL.

11. The vertical memory device of claim 10, wherein the separation layer pattern cuts an upper portion of the channel adjacent to the SSL.

12. The vertical memory device of claim 1, wherein the conductive line and the conductive pattern include a same metal.

13. A method of manufacturing a vertical memory device, comprising:
forming a plurality of insulating interlayers and a plurality of sacrificial layers alternately and repeatedly on a substrate;
forming a plurality of first holes through the insulating interlayers and the sacrificial layers;
forming a plurality of channels in the first holes;
forming a plurality of second holes through the insulating interlayers and the sacrificial layers, a second hole of the plurality of second holes surrounded by a plurality of the first holes;
replacing the sacrificial layers with gate electrodes;
forming a plurality of CSL contacts in the second holes; and
forming a bit line and a CSL line, each of the bit line and the CSL line electrically connected to the channels and the CSL contacts, respectively.

14. The method of claim 13, wherein the first holes and the second holes are formed simultaneously.

15. The method of claim 13, further comprising forming a separation layer pattern which extends partially through the insulating interlayers and the sacrificial layers before the replacing the sacrificial layers with the gate electrodes.

16. A vertical memory device, comprising:
a substrate;
a channel positioned on, and orthogonal to, the substrate;
a conductive pattern parallel to the channel positioned on the substrate, the conductive pattern having a shape that is substantially the same as a shape of the channel;
a bit line electrically connected to the channel; and
a conductive line at an upper portion of the vertical memory device, the conductive line electrically connected to the conductive pattern.

17. The vertical memory device of claim 16, further comprising at least one gate electrode surrounding an outer sidewall of the channel and the conductive pattern.

18. The vertical memory device of claim 16, the conductive pattern is a common source line (CSL) contact and the conductive line is a CSL.

19. The vertical memory device of claim 16, wherein the bit line and the conductive line are at different levels relative to the substrate.

20. The vertical memory device of claim 16, wherein the conductive line includes:
a first conductive line disposed at the same level as that of the bit line; and
a second conductive line disposed at a different level from that of the bit line.
